(19) United States
(12) Patent Application Publication
(10) Pub. No.: US 2009/0256156 A1
(43) Pub. Date: Oct. 15, 2009

(54) Hybrid imaging sensor with approximately equal potential photodiodes

(75) Inventor: Tzu-Chiang Hsieh, Fremont, CA (US)

Correspondence Address: TREX ENTERPRISES CORP., 10455 PACIFIC COURT, SAN DIEGO, CA, 92121, US

(73) Assignee: e-Phocus, Inc

(21) Appl. No.: 12/283,821

(22) Filed: Sep. 15, 2008

Related U.S. Application Data
(63) Continuation-in-part of application No. 12/082,138, filed on Apr. 9, 2008.

(51) Int. Cl. H01L 31/112

(52) U.S. Cl. 257/72; 257/292; 257/E31.073

(57) ABSTRACT

A hybrid MOS or CMOS image sensor. The sensor includes photon-sensing elements comprised of an array of photo-sensing regions deposited in the form of separate islands on or in a substrate. Pixel circuitry is created on and/or in the substrate at or near the edge of or beneath the photon-sensing elements. The photo-sensing elements may be comprised of multiple photo-sensing semiconductor layers or be created in a single photon-sensing semiconductor layer. Special circuitry is provided to keep the potential across the pixel photon-sensing element at or near zero volts to minimize or eliminate dark current. The potential difference is preferably less than 1.0 volt. The circuitry also keeps the small potential difference across the photodiodes constant or approximately constant throughout the charge collection cycle. In preferred embodiments the substrate is a crystalline substrate and the photon-sensing elements are separated from the substrate by a dielectric material except for a hole at the bottom through which the material of the photon-sensing element can be grown epitaxially from the substrate.

### CROSS REFERENCE TO RELATED APPLICATIONS

The present invention is a continuation-in-part of Parent patent application Ser. No. 12/082,138 filed Apr. 9, 2008.

### FIELD OF INVENTION

The present invention relates to imaging sensors and in particular to infrared imaging sensors with special features for substantially reducing or eliminating dark current noise and clock noise.

### BACKGROUND OF THE INVENTION

### CMOS Sensors

Active pixel CMOS sensors are well known. CMOS is an abbreviation for complementary metal oxide semiconductor. An active-pixel sensor (APS) is an image sensor consisting of an integrated circuit containing an array of pixel sensors (each pixel containing a photo-detector and pixel circuitry containing an active amplifier) and reset and readout circuitry. CMOS sensors are produced by a CMOS process and have emerged as an inexpensive alternative to charge-coupled device (CCD) imagers. CMOS APS's consume far less power than CCD's, have less image lag, and can be fabricated on much cheaper and more available manufacturing lines. Unlike CCD's, CMOS APS's can combine both the image sensor function and image processing functions within the same integrated circuit.

CMOS APS's have become the technology of choice for many consumer applications, most significantly the burgeoning cell phone camera market; however, adoption of these APS image sensors has also found inroads in many other growing fields of photography and imaging. These include digital radiography, military ultra high speed image acquisition, high resolution ‘smart’ security cameras as well as many other consumer applications.

A standard CMOS APS pixel consisting of three transistors as well as a photo-detector is shown in FIG. 4A. The photo-detector is a photodiode. Light causes an accumulation, or integration of charge on the parasitic capacitance of the photodiode, creating a voltage change related to the incident light. One transistor M_{RST} acts as a switch to reset the device. When this transistor is turned on, the photodiode is effectively connected to the power supply V_{CC} clearing all integrated charge and resetting the pixel. The second transistor M_{SF} acts as a buffer (specifically, a source follower) and an amplifier which allows the pixel voltage to be observed without removing the accumulated charge. Its power supply V_{CC} is typically tied to the power supply of the reset transistor. The third transistor M_{SEL} is a row-select transistor. It is a switch that allows a single row of the pixel array to be read by the read-out electronics.

A typical two-dimensional array of pixels is organized into rows and columns. Pixels in a given row share reset lines, so that a whole row is reset at a time. The row select lines of each pixel in a row are tied together as well. The outputs of each pixel in any given column are tied together. Since only one row is selected at a given time, no competition for the output line occurs. Further signal conditioning circuitry is typically accomplished on a column basis.

### Constant Gate Bias Transistors

Operation of transistors with constant gate bias is a known technique used to maintain the source voltage of a transistor at a constant value. For example, for n-type transistors operated with 3.3 supply voltage, a gate voltage at about 0.7 volts (the threshold voltage of the transistor) above the desired source voltage will permit current to flow from the drain of the transistor to the source. The current depends upon the voltage drop between drain and source. If the gate voltage is less than 0.7 volts above the source voltage, the transistor is considered “off” and only “off leakage current” can flow through the channel. In modern semiconductor process, the “off leakage current” is negligible. (When the n-type transistor is used as a “digital switch”, the gate voltage is typically set at ground (0 volt) to turn “off” the transistor and the gate voltage is set at the supply voltage to turn the transistor “on”.)

For example in the case of the above n-type transistor having a 0.7 volt threshold operated with a constant gate voltage such as 3.3 volt and with its source connected to one side of a capacitor whose other side is connected to ground and its drain is connected to a supply voltage at 3.3 volts, the current will flow through the channel of the transistor charging the capacitor until the voltage at the source is about 0.7 volt below the gate voltage. That is, 3.3 V minus 0.7 V equals 2.6 V for a constant gate potential. (The 0.7 V in this example is referred to as the transistor threshold and typical values, in modern semiconductor process, of the threshold are about 0.5-0.7 volts for the transistors to be operated with 3.3 V supply voltage.) This will keep the source voltage approximately constant at a voltage of about 0.7 volt below the gate voltage (i.e. 2.6 volts) while allowing current to flow through the transistor to the capacitor.

### Noise Problems in CMOS Active Pixel Sensors

A problem associated with CMOS APS's is that they tend to be susceptible to noise problems. Major problems are reset clock noise and dark current noise. Noise problems typically increase for optical sensors designed to detect longer wavelength, lower energy light.

### Reset Clock Noise

In a typical CMOS sensor, each pixel's sensing node is typically reset many times per second (such as 30 times per seconds) to establish a reference (or reset) condition before each readout. A typical implementation of this reset function is to use a transistor as a “switch” whose gate is electrically connected to a control clock signal from a timing circuit on-chip or off-chip. This control clock signal typically is alternately “on” and “off” on a frame-by-frame basis or row-by-row basis. From the timing generation circuit of this reset clock signal to the channel of the reset transistor inside the pixel, there is impedance (including resistance and capacitance) along the path that is not always constant but may vary with time. It is well known that such impedance has noise associated with it. It is typically a major design task to reduce or eliminate such noise associated with the pixel reset. This type of noise is called “clock noise”.

### Non-Silicon Photodiodes

In most CMOS and CCD, photodiodes are comprised of silicon doped with impurities to produce n and p regions, and sometimes there might be an un-doped intrinsic region separating the n and p regions. It is known that photodiodes can be produced with materials other than silicon. These materials include Germanium, Indium Gallium Arsenide, Indium Antimonide and Indium Arsenide. The photodiodes made of Germanium, Indium Gallium Arsenide, Indium Antimonide or Indium Arsenide can be made to detect photons in the spectral range from near infrared, short wave infrared, mid-wave infrared and long-wave infrared. However, a critical weakness of these photodiodes is that they are typically much more subject to dark current. As a result of it, the conventional pixel circuits can not be used in conjunction with such photodiodes for imaging sensor array applications.

### Dark Current

Dark current is the relatively small electric current that flows through a photosensitive device such as a photodiode, or charge-coupled device even when no photons are entering the device. Dark current tends to increase with increases in the voltage potential applied across the photodiode. Photodiodes made of material such as crystalline and hydrogenated amorphous silicon exhibit very low dark current. However, photodiodes made of germanium on silicon substrate show very large dark current. Photodiodes formed in bulk crystalline germanium have somewhat lower but still very high dark leakage for image sensor applications. A germanium-based photo-detector concept has been proposed in U.S. Pat. No. 7,288,825. This technique proposes a three terminal p-n-p photo-detector where one of the p-n junctions is used to collect unwanted leakage current leaving the other p-n junction to function as a photodiode with low dark current leakage. This patent is incorporated by reference herein.

### Prior Art Pinned Photodiode Sensors

Pinned photodiodes sensors are well known in the prior art. Following are examples of patents describing CMOS sensors employing pinned photodiodes: U.S. Pat. Nos. 5,625,210; 5,880,495; 5,904,493; 6,297,070; 6,566,697; 6,967,120; and 7,115,855. All of these patents are incorporated herein by reference.

### Correlated Double Sampling

A known technique to eliminate clock noise is based on the fact that once the reset switch has been turned “off”, the clock noise will not significantly change the condition at the sense node. This allows one to completely remove clock noise at the sensing node by the “correlated double sampling” (CDS) technique. CDS eliminates clock noise by determining the difference between a sample taken at the sense node after the reset as the reference level and a second sample after the signal charges have been transferred to the sense node. There is no reset to the sense node between these two samplings. As a result of it, CDS can eliminate reset noise to the sense node very effectively because the noise caused by reset clock does not occur between the reference sampling and the signal sampling.

### Uncorrelated and Correlated Double Sampling

### Three Transistor Active Pixel Sensors—Uncorrelated Double Sampling

In the simplest CMOS active pixel sensor designs, there are rows and columns of pixels with each pixel containing a photodiode region and three transistors. In this design, the charge collection node, charge integration node and charge sensing node is the same node physically or electrically connected with negligible impedance. Two of the transistors are “passive in nature, one of the “passive” transistors is used to reset the charge sensing/integration/collection node (the SIC node) and one is used to address each individual row of pixels. The third transistor is an active element functioning as a source-follower to provide a pixel output voltage based upon a charge signal at the SIC node produced in the photodiode region. In this three-transistor pixel circuit, reset and signal readouts occur in the following sequence: (1) reset the SIC node, (2) integrate charges for a period of time (exposure time), (3) select the row, (4) readout the pixel signal after illumination for every pixel within the selected row and (5) reset the SIC node of the selected row immediately and readout for the second time to establish a reference voltage level. The net pixel signal is defined by the differential between Steps 4 and 5. (6) Repeat steps 1-5 continuously. The difference between these signals can be determined using analog techniques before the signals are digitized or digitally after digitization. The purpose of Step 1 is to reset the SIC node to be free of carriers to establish a reference level before charge integration starts. The purpose of Step 5 is to reset the SIC node in order to establish a reference voltage level. The proper readout sequence ought to be “reset the SIC node” first before any readout of real signal voltage level. In this simplest three-transistor design, the charge integration node and charge sensing node circuit-wise is the same node. Therefore one can not perform Step 5 ahead of Step 4; if so, the charges integrated at the SIC node would be lost. As a result, one has no choice but to readout the signal voltage level first as done in Step 4 then reset and measure the reference voltage level in a Step 5. As a result uncertainty results from the noise associated with the reset to the SIC node occurring in between the two readout steps. Thus, the signal and reference voltages are not correlated so this readout scheme is called un-correlated double sampling.

### Four Transistor Active Pixel Sensors—Correlated Double Sampling

To achieve low noise sensing, it is desirable to make the readout totally correlated under which uncertainty due to the reset clock noise onto the charge sensing node can be cancelled completed. In order to do this, the first design goal is to isolate the charge integration node from the charge sensing node. This can be accomplished with a fourth transistor functioning as a switch to isolate the charge integration node from the charge sensing node. With such a design, one can then operate the pixel with the following sequence: (1) reset the charge integration node, (2) integrate charges for a certain period of time (exposure time), (3) reset the charge sense node, (4) select the row, (5) readout the signal at the charge sense node, (6) transfer the charge from the charge integration node to the charge sense node, and (7) readout the signal at the charge sense node the second time. This sequence is then repeated for other rows. Since there is no reset to the charge sense node between Steps (5) and (7); therefore, the signal detected at Step (7) is correlated to the “start condition” at Step (5). As a result of it, any uncertainty to the charge sensing node caused by the reset control signal on the reset transistor is avoided. Since the sense node is read twice in a correlated manner, once immediately after reset and once after the charges are transferred from the charge integration node, with no reset in between, this readout scheme is called correlated double sampling. The purpose of correlated double sampling is to eliminate the clock noise of the reset transistor M_{RST} into the charge sensing node. In this four transistor pixel design, the charge integration node is reset only once in Step 1 before charge integration starts. This is typically done by closing (turning “ON”) the fourth transistor separating the charge integration node from the charge sensing node and resetting both nodes prior to the charge integration step. Typically, this reset is done on a row-by-row basis, which is called rolling shutter. If one uses a mechanical shutter with this kind of sensors, one can reset the charge integration nodes of all the pixels at the same time on a frame basis. After the integration time, one can then close the mechanical shutter and readout the signal one row of a time.

### Four Transistor Pixel with Pinned Photodiode

FIG. 4 shows a prior art, four transistor CMOS APS pixel cell with a pinned photodiode 400 and a transfer-gate NMOS transistor 410 similar to one described in U.S. Pat. No. 5,625,210 which is incorporated by reference herein. Charges generated in a pinned photodiode 400 are collected and integrated at a charge integration node 402 and sensed at a charge sensing node 403. The transfer gate transistor 410, when turned off, isolates a charge sensing node 403 from charge integration node 402. The pinned photodiode 400 is specially engineered such that, when the transfer gate 410 is turned on, the integrated charges at charge integration node 402 can be completely transferred to the charge sensing node 403. The pinned photodiode is a conventional p-n junction with a top surface of the n region doped heavily with p-type doping. The benefits of this shallow heavy p-type implant is well known and widely used in the industry; and it has been reviewed in detail by A. J. Theuwissen, IEEE Transactions On Electron Devices, Vol. 53, No. 12, December 2006. This heavy p-type implant would flood the interface with acceptors which could fill the interface states at the SiO₂/Si interface with holes and produce a region of negative charge near the top surface of the n region. As a result of this negative charge, all electrons accumulated at charge integration node 402 during the photon integration phase will be shielded from the SiO₂/Si interface region and avoid being captured and re-emitted by the interface states. Therefore, the charges can be transferred completely to the charge sensing node 403 when gate 410 is turned “ON” (i.e. when this switch is closed). This is to eliminate any in-sufficient charge transfer that could otherwise result in “image lag”. It has been observed that this could also reduce the dark noise caused by the interface states.

At the beginning of the operation, both the reset transistor and the transfer gate transistor are turned ON and the photodiode 400 D_{PH} at reset is reset to a known voltage reverse biasing photodiode 400 Dₚₕ and establishing a reset potential at node 402 and at node 403. After reset, both the reset transistor and the transfer gate transistor will be tuned OFF and photo-generated and thermally-generated electrons start accumulating in the depletion regions of the p-n junction of the photodiode 400 D_{PH} reducing the electric potential at node 402. This period of charge accumulation is referred to as a charge integration time. (The p-n junction thus is serving the function of a capacitor. In FIG. 4 Applicant illustrates this capacitive effect with a capacitor symbol C_{STO}. Applicant uses dashed lines here to represent an equivalent capacitor in order to distinguish it from a typical metal-insulator-metal capacitor. This equivalent capacitance is a by-product of a p-n junction and its effect needs to be considered in circuit simulations. This is a common practice in semiconductor industry. Of course, one can implement a conventional capacitor made of metal-insulator-metal and connected in between this node and ground. This would require an increase in the size of the pixel area so these conventional capacitors are not used in typical pixel designs. The total capacitance is the combination of the p-n junction capacitance plus any additional capacitance associated with any metal-insulator-metal type capacitance.) At the end of the charge integration time, charge sensing node 403 is reset by turning on reset transistor 411. (This resetting has no effect on charge integration node 402 since switch 410 is turned off.) Then the signal level at the sense node 403 is read to establish a reference voltage. The next step is to pulse transfer switch 410 to transfer the integrated charge from the charge integration node 402 to charge sensing node 403. These pixels each include a diode D_{SEN} at sensing node 403, which is also formed near the regions at the p-n junction. This diode functions as a capacitor and as above Applicant indicates its capacitive effect with dashed lines. Then the signal at the charge sensing node 403 is read a second time. The differential between the voltage levels read before and after transistor switch 410 is pulsed represent the signal level detected by the photodiode. This readout technique is called correlated double sampling with which any uncertainty related to the “reset to the sensing node 403” is removed since both the reference voltage and signal voltage levels are all referred to the same condition at the charge sensing node 403 immediately after the reset and there is no reset to the sense node in between the reading of the reference voltage and the reading of the integrated signal voltage. This is the state of the art technique to achieve the lowest “pixel reset clock noise” known in the industry.

In this arrangement as shown in FIG. 4, four NMOS transistors are required for each pixel cell, i.e., reset transistor 411, source-follower transistor 412, row-select transistor 413, and transfer-gate transistor 410. A simplified cross-section view of the prior art pinned photodiode pixel is illustrated in FIG. 4B.

### Bump Bonding

Bump bonding is a sensor technology relying on a hybrid approach. With this approach, the readout chip and the photo-detector portions are developed separately, and the sensor is constructed by flip-chip mating (also called bump bonding) of the two. This method offers maximum flexibility in the development process, choice of fabrication technologies, and the choice of sensor materials. However, it is very difficult and expensive to use this flip-chip process to make image sensors of multi-million pixels. And in today's state-of-the-art bump bonding technique, the bumps mating the readout chip and photo-detector are larger than 20 um; therefore, it is very difficult to scale up to multi-million pixel image sensors using this technique.

### The Need

What is needed is a monolithic image sensor responsive to low energy light with special MOS or CMOS pixel circuitry for minimizing dark leakage current, and has similar flexibility as the traditional hybrid image sensors but with much better capability to scale up to multi-million pixel image sensors.

### SUMMARY OF THE INVENTION

The present invention provides a hybrid MOS or CMOS based image sensor. The sensor includes photon-sensing elements comprised of an array of photo-sensing elements deposited in the form of separate islands on or in a substrate. Pixel circuitry is created on and/or in the silicon substrate at or near the edge of or beneath the photon-sensing elements. The photo-sensing elements may be formed with a stack of photo-sensing semiconductor layers or created in a single photon-sensing semiconductor layer. Special circuitry is provided to keep the potential across the pixel photon-sensing element at or near zero volts to minimize or eliminate dark current. The potential difference is preferably less than 1.0 volt. The circuitry also keeps the small potential difference across the photodiodes constant or approximately constant throughout the charge integration cycle. In preferred embodiments the substrate is a crystalline substrate and the photon-sensing elements are separated by a dielectric layer from the substrate except for a small hole through which the material of the photon-sensing element can be grown epitaxially. Photodiodes are used in the preferred embodiments as the photo-sensing elements.

Preferred embodiments are adapted for correlated double sampling to substantially reduce or eliminate clock noise. Preferred embodiments include pixel circuitry defining a charge collection node on which charges generated inside a photodiode region are collected, a charge integration node, at which charges generated in said pixel are integrated to produce pixel signals, a charge sensing node from which reset signals and the pixel signals are sensed. The charge collection node and charge integration node are physically separated from each other. However, the charge integration node and charge sensing node can be electrically shorted to be considered as a common node or separated by other circuit elements as two separated nodes. In this separation Applicant preferably uses a constant gate bias transistor whose gate is held at a substantially constant bias voltage, about 1.2 V, during the charge integration cycle. Applicant makes this bias voltage programmable in the range of 0.7V to 2.1V to fine tune the overall sensor performance. This transistor maintains the voltage at the charge collection node at a constant value, at least during the charge integration cycle. The charge collection node is considered electrically short to the one of the electrode connecting to the photodiode. This constant voltage eliminates the need to use the built-in capacitance of the photodiode to store signal charges. The capacitance associated with the integration node is reset to produce a potential at the integration node of about 2.6 volts at the beginning of the charge integration cycle in the preferred embodiment. The constant gate bias transistor allows current flowing from the charge integration node to the charge collection node until the charge collection node is charged up to slightly (a few tenths of a volt) below the constant gate bias. After reset, the charge integration node is left “floating”.

During charge integration cycle, electron-hole pairs will be generated with electrons migrating to the charge collection node through one end of the photodiode and holes migrating to the other end of the photodiode. Because of the accumulation of the additional electrons at the charge collection node, its voltage potential will drop. This will in effect “turn on” the constant gate biased transistor and let current flow from the charge integration node (electrically short to the drain of the constant gate biased transistor) until the voltage at the charge collection node (electrically short to the source of the constant biased transistor) goes back up to slightly (a few tenths of a volt) below the gate bias and then the current flow will stop. The current flow to maintain the charge collection node at a constant voltage continues to lower the voltage at the charge integration node throughout the charge integration period. The amount of the voltage drop at the charge integration node is proportional to the amount of charges generated inside the photodiode.

This novel design resolves the concern of incomplete charge transfer on the charges stored on the photodiode (and its associated circuitry) since there is no charge transfer from the photodiode region during the signal readout cycles. Charge transfer from photodiode regions during readout can be a serious problem where the charges stored on the photodiode needs to travel through vias and interlayer metal connectors in order to get to the charge sensing node. This travel path can not be fabricated with perfection in real practice; therefore, incomplete charge transfer is expected. Using a constant gate bias transistor to maintain the charge collection node at a constant value, eliminates the need of relying on the effective capacitance of the photodiode and fringe capacitance along the conducting path from the photodiode to the charge collection node as a part of a charge integration capacitance. Therefore, since signal charges are not stored at, and readout from, the charge collection node; any imperfection of the path will not affect the integrity of the signal. Use of the constant gate bias is also important where the photodiode material is naturally subject to dark current leakage.

It is as important to provide substantially complete charge transfer from the charge integration node to the charge sensing node. To do this, Applicant in preferred embodiments heavily dopes the surface of the storage n-p junction diode to fill the surface regions with acceptors to avoid or minimize the trapping and re-emission of electrons by the surface defects. In some preferred embodiments of the present invention five transistors per pixel are used to provide CDS capability.

The Applicants' present invention can be adapted to work as an “electronic shutter”.

### BRIEF DESCRIPTION OF THE DRAWINGS

FIGS. 1A through 1F describes a first method for creating germanium based photodiode island regions on a silicon substrate.

FIGS. 2A through 2F describes a second method for creating germanium based photodiode island regions on a silicon substrate.

FIGS. 3A through 3F describes a third method for creating germanium based photodiode island regions on a silicon substrate.

FIG. 4 shows a prior art four transistor CMOS active pixel sensor cell.

FIG. 4A shows a prior art three transistor CMOS active pixel sensor cell

FIG. 4B is a simplified cross sectional view of the cell shown in FIG. 3.

FIG. 5 is a five transistor pixel cell.

FIG. 5A is similar to FIG. 5; the only difference is the positive side of the photodiode is grounded in 5A.

FIG. 6 is a drawing of a preferred embodiment utilizing readout circuits shared among four pixels.

FIG. 7 is a drawing showing timing features of preferred embodiments.

FIGS. 8 and 8A show details of a technique for minimizing or eliminating dark current noise.

FIG. 9A shows an array of pixels with p-i-n junction photodiodes in the island region inside a silicon substrate and by the pixel circuits, where the i-layer is formed vertically between p-type and n-type regions.

FIG. 9B shows an array of pixels with p-i-n junction photodiodes; where the p-type and n-type regions are formed inside the intrinsic region in the island regions inside a silicon substrate and by the pixel circuits.

FIG. 9C shows an array of pixels with p-n junction photodiodes; where the p-n junction is formed in the island regions inside a silicon substrate and by the pixel circuits.

FIG. 9D shows an array of pixels with p-n junction photodiodes which is grown from the substrate and extended to cover a portion or all of the pixel circuitry.

FIGS. 10A and 10B show versions of a four transistor photodiode array with photodiodes described in FIG. 1F.

FIGS. 10C and 10D show versions of a five transistor photodiode array with photodiodes described in FIG. 1F.

FIGS. 11A and 11B show versions of a four transistor photodiode array with photodiodes described in FIG. 2F.

FIGS. 11C and 11D show versions of a five transistor photodiode array with photodiodes described in FIG. 2F.

FIGS. 12A and 12B show versions of a four transistor photodiode array with photodiodes described in FIG. 3F.

FIGS. 12C and 12D show versions of a five transistor photodiode array with photodiodes described in FIG. 3F.

### DETAILED DESCRIPTION OF PREFERRED EMBODIMENTS

### Photo-Sensing Element Islands Array on Silicon Substrates

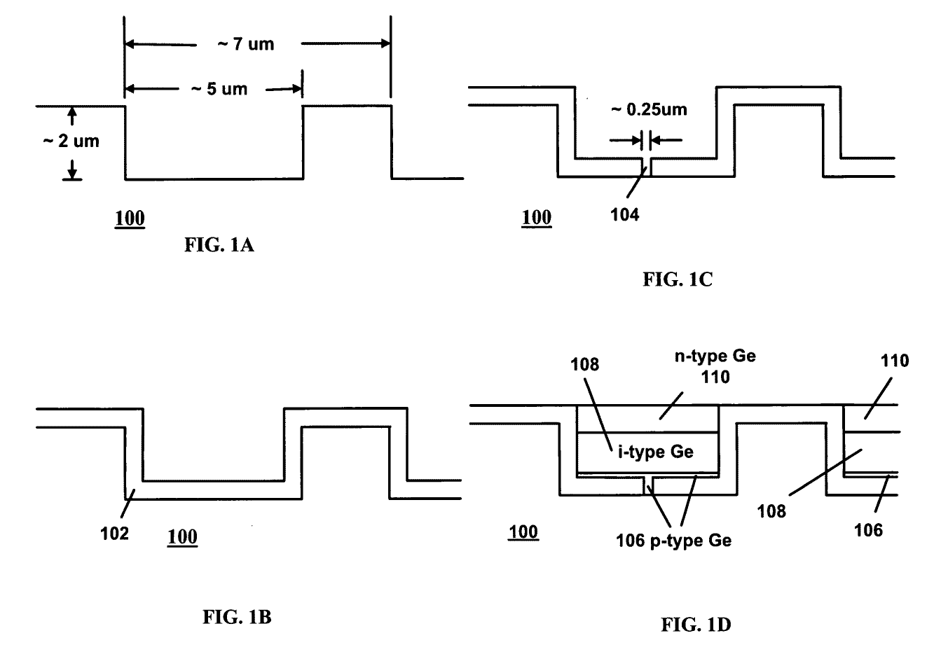

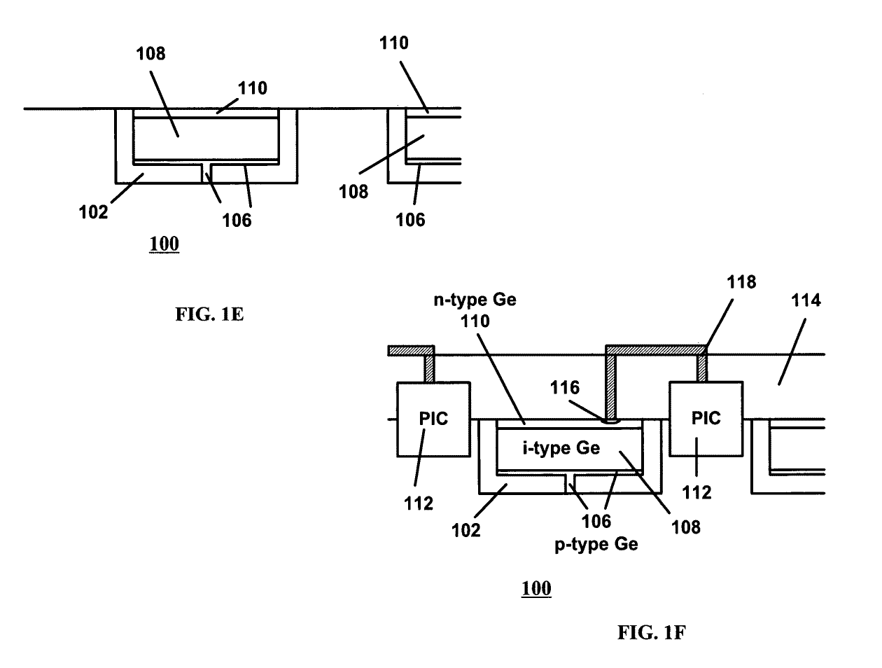

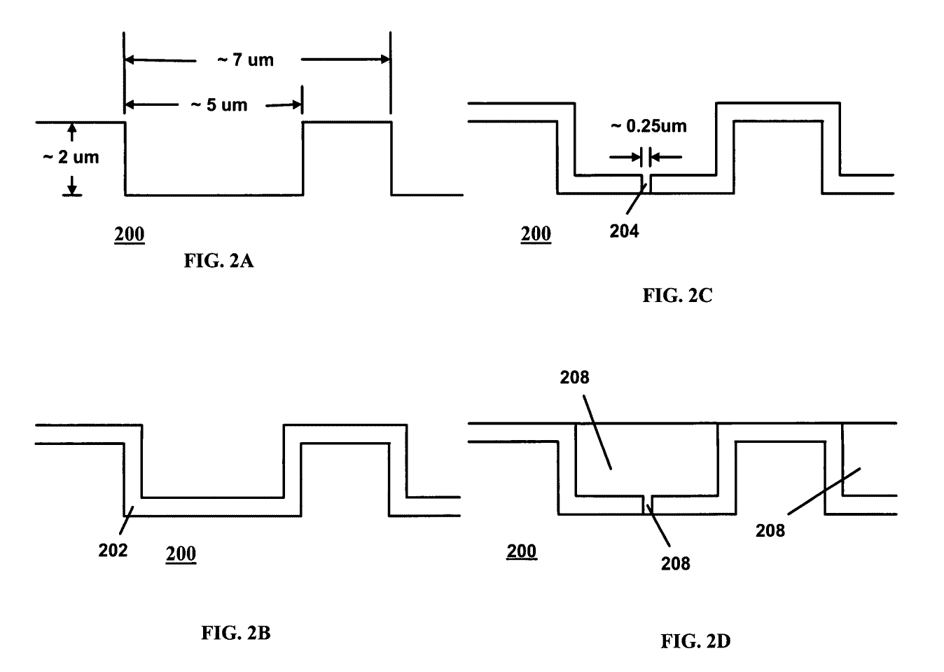

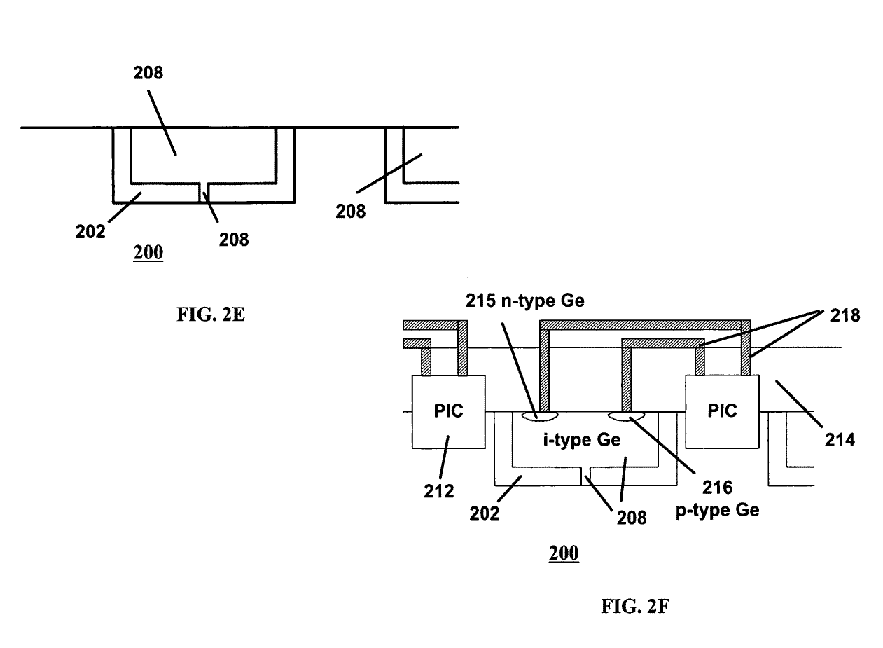

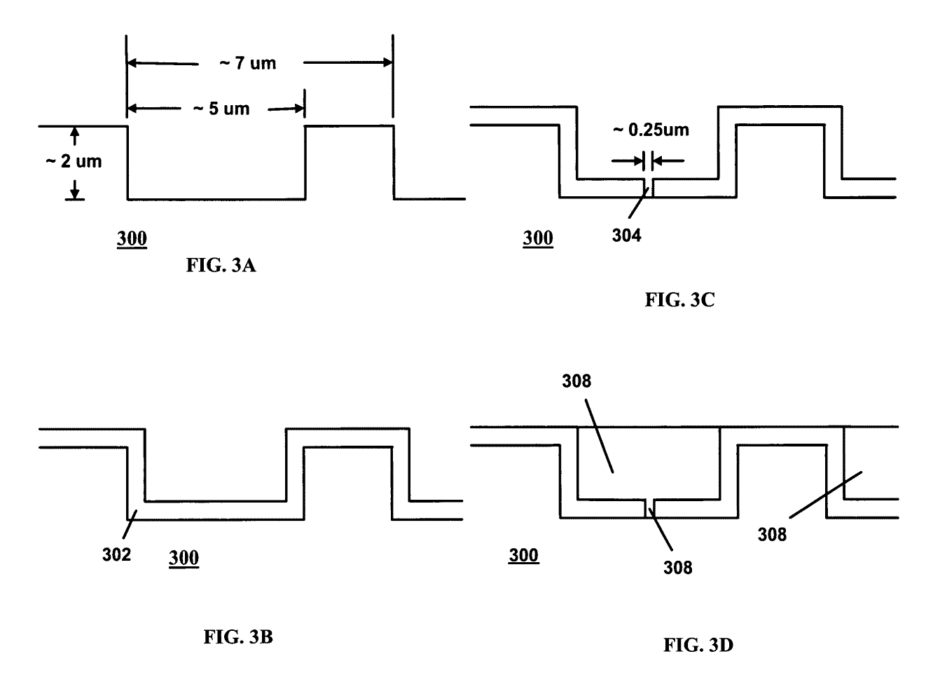

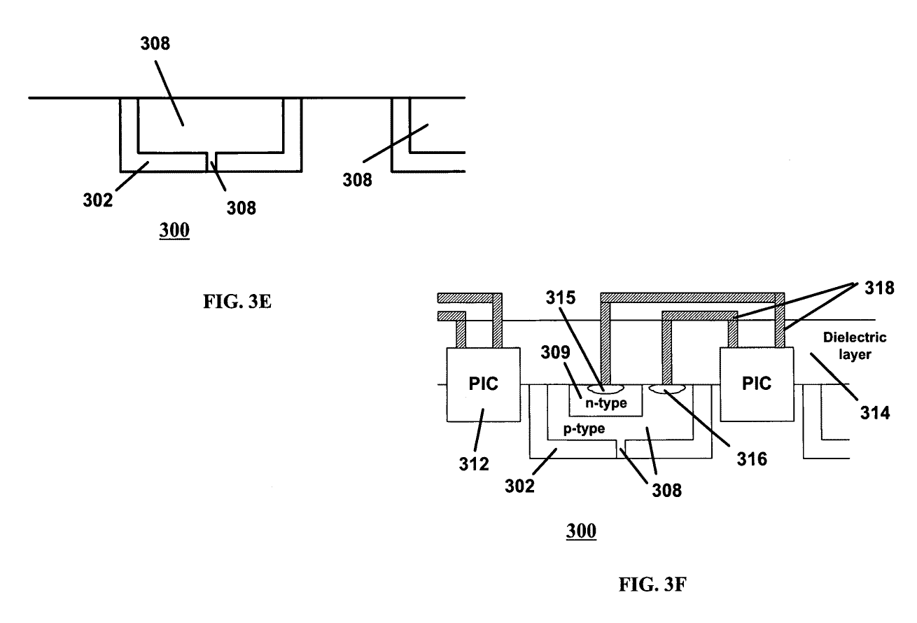

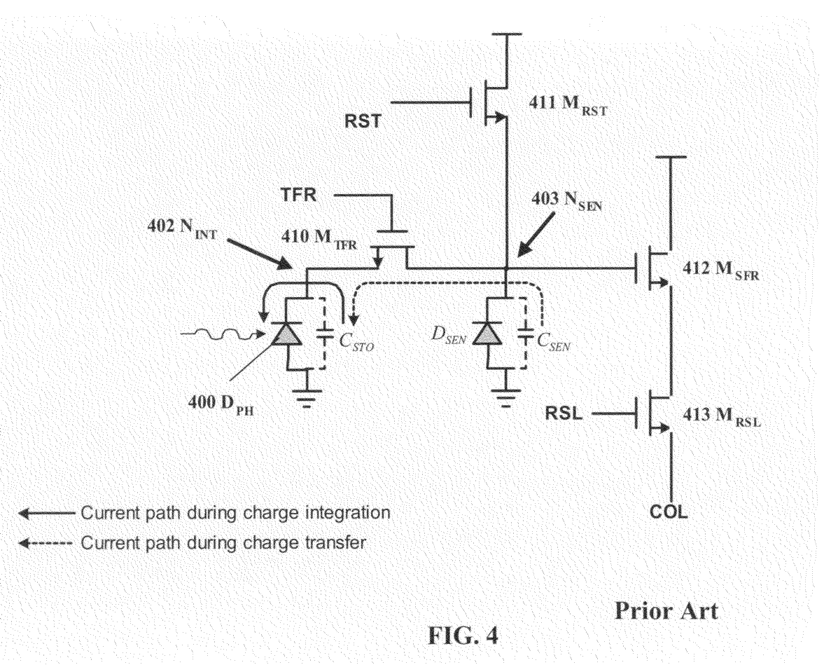

Preferred embodiments of the present invention may be described by reference to the drawings. FIGS. 1A through 1F describe a first preferred method for creating an array of germanium-based photodiodes islands in a silicon substrate. This method results in vertical p-i-n photodiodes. FIGS. 2A through 2F describe a second preferred method of creating an array of germanium-based photodiodes islands in a silicon substrate. This second method results in horizontal p-i-n photodiodes. FIGS. 3A through 3F describe a third preferred method of creating an array of germanium-based photodiodes islands in a silicon substrate. This third method results in p-n junction photodiodes.

The silicon substrate material used in the methods described below is typical silicon substrate material used in semiconductor industry; could be either a p-type silicon substrate alone or a p-type epitaxial layer of about 4-6 micron thick on top of a p-type substrate. In the disclosure of this invention, the author makes no differentiation between these two types of substrates and refers them as “substrate”.

### First Method—Vertical p-i-n Photodiode

As indicated above, the first preferred method uses a silicon substrate and the preferred material for the photodiode islands is a stack of epitaxially grown germanium layers.

### Basic Process of the First Method

As shown in FIGS. 1A to 1F,

### Step 1:

As shown in FIG. 1A, an array of cavities about 5 microns×5 microns and about 2 microns deep are etched into the surface of a single crystal silicon substrate with a 7 micron pixel pitch in both horizontal (X and Y) directions. The number of pixels in the array can be few to very many. A preferred array is a nominal 2 million pixel (1600×1200) array.

### Step 2:

An oxidation process is used to make a roughly 6,000A oxide layer on the entire wafer, as shown in FIG. 1B.

### Step 3:

Holes 104 of about 2,500 A are opened near the center of the cavity through the oxide layer. The location of the little holes is not critical as long as the hole penetrates clear through the oxide layer to the substrate to permit the substrate to provide a seed source of crystallinity for epitaxial layers that will be grown in the cavity. See FIG. 1C.

### Step 4:

In sequence epitaxially grow a p-type germanium (Ge) layer 106, an intrinsic germanium layer 108 and n-type germanium layer 110 as shown in FIG. 1D to form a vertical p-i-n photodiode structure. The top n-layer may be overgrown beyond the surface of the oxide-protected silicon substrate areas.

### Step 5:

Chemical mechanical polish (CMP) is applied to remove the excessive Ge in the cavity regions and the oxide layer from the silicon regions to create an array of Ge island regions as shown in FIG. 1E. This CMP practice is a routine practice used in today's semiconductor fabrication process. At the end of CMP process, the top surface of the island regions would be flushed to the top surface of silicon regions. The thickness of n-layer as well as p-layer can be a few tens to a few hundreds of Angstroms, the bulk of the photodiode thickness is in the intrinsic layer 108.

### Step 6:

The wafers out of Step 5 are processed as a regular silicon wafer to make pixel circuits (PIC) 112 in the silicon regions, as shown in FIG. 1F. In sections to follow, several pixel circuit designs are proposed and described in detail. As a part of Step 6 a higher doped n(+) region near the top of the n-layer inside the photodiode islands is produced to provide an electrical contact region in the n-layer. A ground contact is provided through the hole 104 into substrate 100. In the course of these efforts the entire surface of the photodiode array is covered by a dielectric layer 114 such as silicon oxide or silicon nitride or a combination of both that is transparent to visible as well infrared light.

In this implementation, the p-layer of the p-i-n photodiode is electrically connected to an external bias voltage through the p-type silicon substrate; which would create a vertical p-i-n photodiode structure. The photodiode would be reverse-biased if a bias voltage applied to the n-layer is higher than the bias voltage to the p-layer. As explained in U.S. Pat. No. 7,012,314, which has been incorporated herein by reference, germanium in crystal form can be epitaxially grown with or without lattice mismatch buffer layers from the seed of the silicon substrate.

### Second Method—Lateral p-i-n Photodiode

The second preferred method also uses a silicon substrate and the preferred material for the photodiode islands is epitaxially grown intrinsic germanium.

### Basic Process of the Second Method

As shown in FIGS. 2A to 2F:

### Step 1:

As shown in FIG. 2A, an array of cavities about 5 microns×5 microns and about 2 microns deep are etched into the surface of a single crystal silicon substrate with a 7 micron pixel pitch in both horizontal (X and Y) directions. The number of pixels in the array can be few to very many. A preferred array is a nominal 2 million pixel (1600×1200) array.

### Step 2:

An oxidation process is used to make a roughly 6,000A silicon oxide layer 202 on the entire wafer as shown in FIG. 2B.

### Step 3:

Holes 204 of about 2,500 A are opened near the center of the cavity through the oxide layer as shown in FIG. 2C. The location of the little holes is not critical as long as the hole penetrates clear through the oxide layer to the substrate to permit the substrate to provide a seed source of crystallinity for epitaxial layers that will be grown in the cavity.

### Step 4:

An intrinsic epitaxial Ge layer 208 is grown in the cavity as shown in FIG. 2D. This layer may be overgrown beyond the oxide-protected silicon substrate regions.

Step 5: Chemical mechanical polish (CMP) is applied to remove the excessive Ge in the cavity regions and the oxide layer from the silicon regions to create an array of Ge island regions as shown in FIG. 2E. At the end of CMP process, the top surface of the island regions would be flushed to the top surface of silicon regions.

Step 6: The wafers out of Step 5 are processed as a regular silicon wafer to make pixel circuits 212 (PIC) in the silicon regions. In sections to follow, several pixel circuit designs are proposed and described in detail. As a part of Step 6 an n-type region 215 and a p-type region 216 near the top of the intrinsic semiconductor regions are produced to form a lateral p-i-n photodiode. In the course of these efforts the entire surface of the photodiode array is covered by a dielectric layer such as silicon oxide or silicon nitride or a combination of both that is transparent to infrared light.

### Basic Process of the Third Method

As shown in FIGS. 3A to 3F,

### Step 1:

As shown in FIG. 3A, an array of cavities about 5 microns×5 microns and about 2 microns deep are etched into the surface of a single crystal silicon substrate 300 with a 7 micron pixel pitch in both horizontal (X and Y) directions. The number of pixels in the array can be few to very many. A preferred array is a nominal 2 million pixel (1600×1200) array.

### Step 2:

An oxidation process is used to make a roughly 6,000A silicon oxide layer 302 on the entire wafer as shown in FIG. 3B.

### Step 3:

Shown in FIG. 3C, holes 304 of about 2,500 A are opened near the center of the cavity through the oxide layer. The location of the little holes is not critical as long as the hole penetrates clear through the oxide layer to the substrate to permit the substrate to provide a seed source of crystallinity for epitaxial layers that will be grown in the cavity.

### Step 4:

A p-type germanium layer is grown in holes 304 and in cavity 308 as shown in FIG. 3D. This layer may be overgrown beyond the oxide-protected silicon substrate regions.

### Step 5:

Chemical mechanical polish (CMP) is applied to remove the excessive Ge in the cavity regions and the oxide layer from the silicon regions to create an array of Ge island regions as shown in FIG. 3E. At the end of CMP process, the top surface of the island regions would be flushed to the top surface of silicon regions.

Step 6: The wafers out of Step 5 are processed as a regular silicon wafer to make pixel circuits 312 in the silicon regions. In sections to follow, several pixel circuit designs are proposed and described in detail. As a part of Step 6 an n-type region 309 near the top of the p-type semiconductor regions is produced to form a p-n junction photodiode and doped conductive regions 315 and 316 are provided for connection of conductive leads 318 which connect the photodiode region to the pixel circuit 312. In the course of these efforts the entire surface of the photodiode array is covered by a dielectric layer such as silicon oxide or silicon nitride or a combination of both that is transparent to infrared light.

### Pixel Circuits

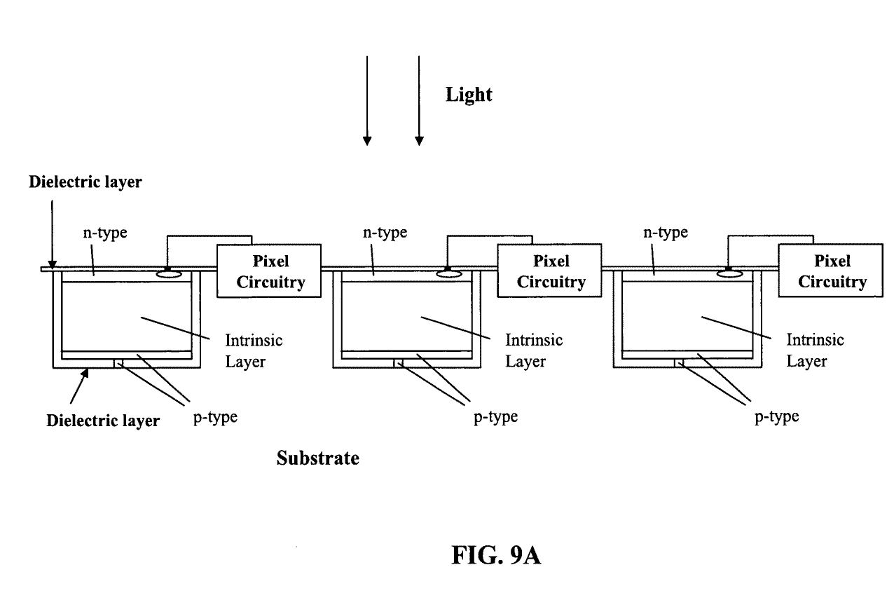

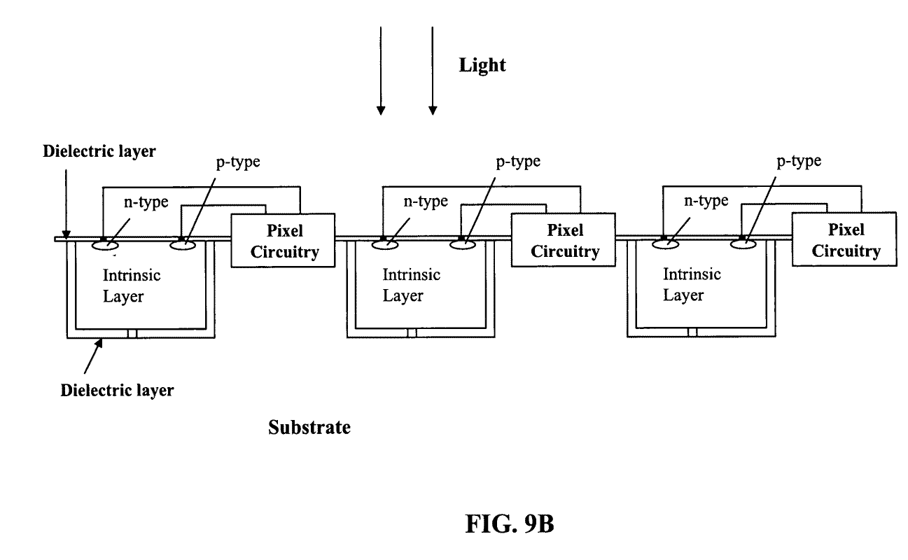

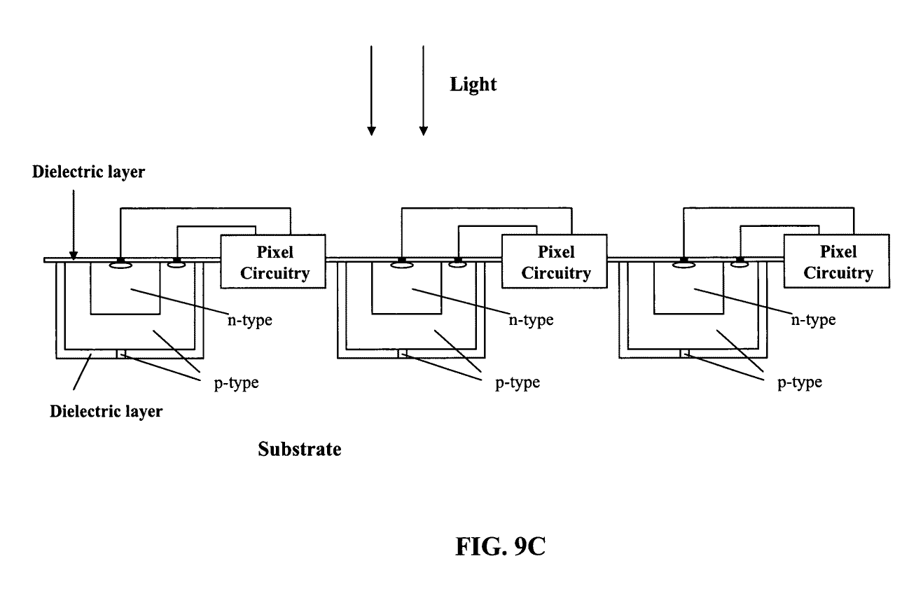

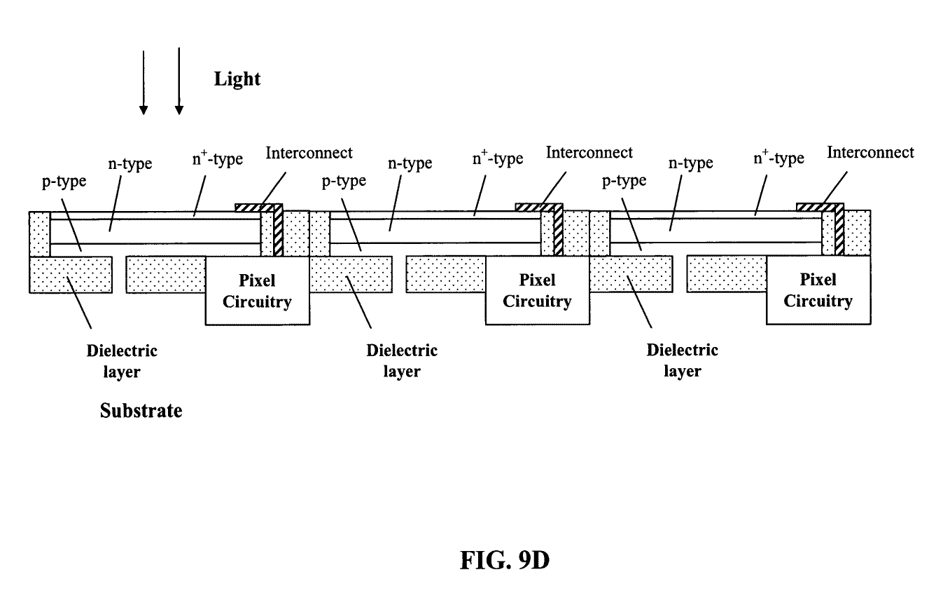

As indicated above these preferred embodiments provide photodiode arrays that are very sensitive to low-energy infrared light photons. A major problem with sensors fabricate to detect infrared photons are typically subject to serious dark current problems and clock noise. The detailed pixel circuit designs that follow are proposed to deal with these problems. FIGS. 9A, 9B and 9C indicate the general layout of pixel arrays fabricated in accordance with the procedures described in the preceding sections. FIG. 9D is a derivative of FIG. 9C, where the photo-sensing element is extended to cover a portion or all of the pixel circuitry.

### First and Second Pixel Circuit Designs

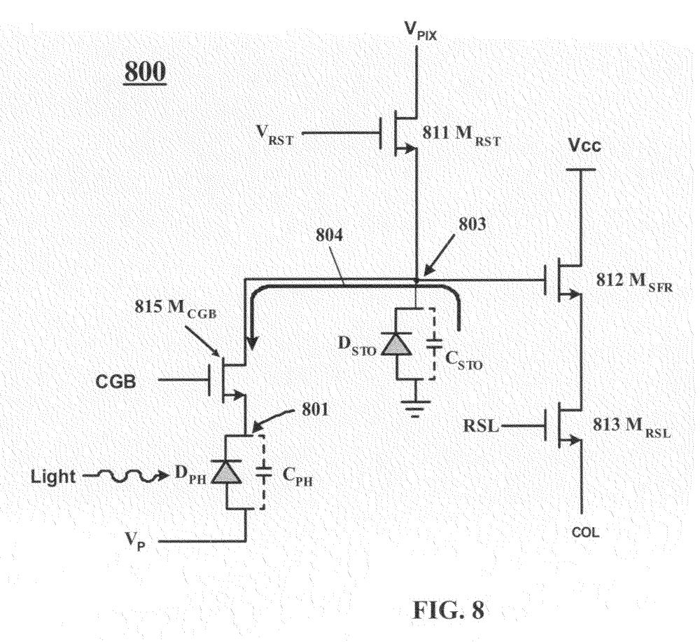

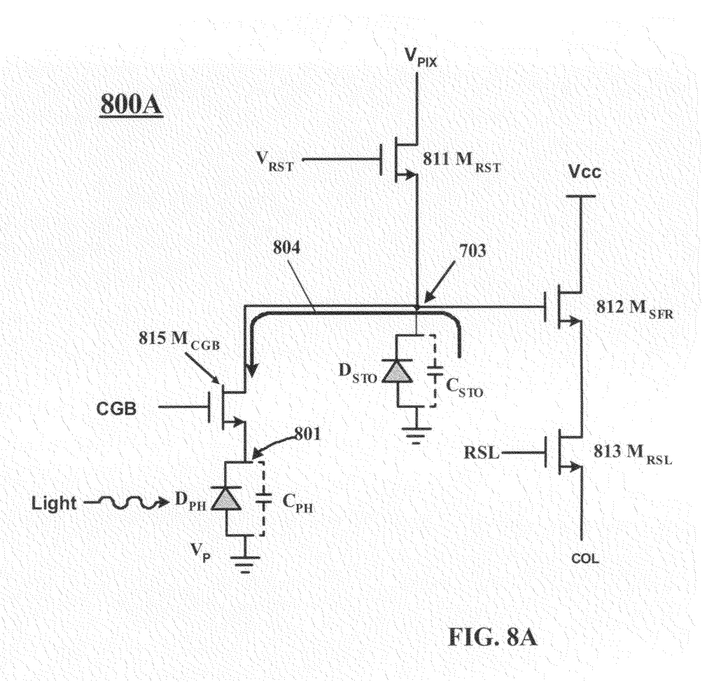

First and second preferred pixel circuit designs are shown in FIGS. 8 and 8A. These are four transistor CMOS pixel circuits similar to pixel circuits described in the parent patent application Ser. No. 12/082,138 which has been incorporated herein by reference. These pixel circuits are typically many pixel circuits in an array of pixel circuits. The number could range from just a few pixels to several million pixels. For example Applicant and his fellow workers have designed and had fabricated sensors with 300 thousands, 2 millions, 36 million pixels and have even designed sensors with more than 150 million pixels.

This four transistor design, as shown in FIGS. 8 and 8A, includes a row select transistor 813 M_{RSL}, a source follower transistor 812 M_{SFR}, a reset transistor 811 M_{RST} and a constant gate bias transistor 815 M_{CGB}. The constant gate bias transistor assures that the pixel electrode at node 801 remains at an approximately constant potential throughout the charge integration process during each integration period which typically may be about 1/30 of a second. The constant gate bias transistor 815M_{CGB}, an NMOS transistor, maintains the potential at node 801 at a potential equal to the potential at the gate of M_{CGB} minus the threshold of the gate bias transistor. This threshold is dependent on the design and fabrication process of the transistor but is typically about 0.5˜0.7 volts.

This circuit includes two diodes, photodiode D_{PH} having an inherent capacitance indicated as C_{PH} and storage diode D_{STO} having an inherent capacitance C_{STO}. The storage diode in the preferred embodiments is a p-n junction diode, which can be made as simple as an n-type diffusion region of the source of the reset transistor 811 M_{RST} interfacing to the p-type substrate.

At the beginning of each integration cycle, row reset transistor M_{RST} is closed (turned ON) to permit the charging of the inherent capacitance of storage diode D_{STO} to a positive potential of about +3.3 volts minus a threshold of the NMOS transistor M_{RST} volts in a soft reset scheme to be described later. Photodiode electrode V_{P} is maintained at less than 1.0 volt above ground potential and the potential at node 801 is matched to V_{P} to within +/−10 volt. In this circuit light illuminating photodiode D_{PH} produces a flow of electrons that pass through constant gate bias transistor and accumulate temporally on storage diode D_{STO} discharging it by an amount determined by the intensity of the illumination and the efficiency of the photodiode to create signal charges after light is absorbed. This flow of electrons is indicated by current flow arrow 804 directed in the direction opposite the direction of the electron flow. At the conclusion of each integration cycle, the charge on D_{STO} is read out from source follower transistor 812 M_{SFR} using row select switch 813 M_{RSL}.

The above circuit description is substantially the same as descriptions in parent application Ser. No. 12/082,138. In the preferred embodiment, the p-type electrode is maintained at a voltage V_{P} equal to less than 1.0 volts and that the potential at node 801 is maintained constant and matched to V_{P} to within +/−1.0 volt. In other preferred embodiments the potential at node 801 is maintained constant and matched to V_{P} as closely as feasible, preferably within +/−0.2 volt. A special preferred embodiment of the present invention is shown in FIG. 8A which is exactly the same as FIG. 8 except V_{P} is at ground potential. With the potential across the photodiode layer at approximately zero, dark current flow is minimized or eliminated to be negligible compared to photon-generated current.

Without the present four transistor invention, the voltage potential across the photodiode structure would not be held constant, typically swinging between a reverse bias of −1 volt to −2.5 volts. If the dark leakage current is high, this dark leakage could saturate the storage capacitor before the photon-generated signal can be large enough during the integration time to provide a meaningful signal. This invention basically removes this constraint and not only provides a voltage potential across the photodiode to be constant but also assures that it is very close to the “short circuit” condition to reduce the dark leakage contribution to the overall signal. (“Short circuit” implies zero potential difference.)

### Third and Fourth Pixel Circuit Designs

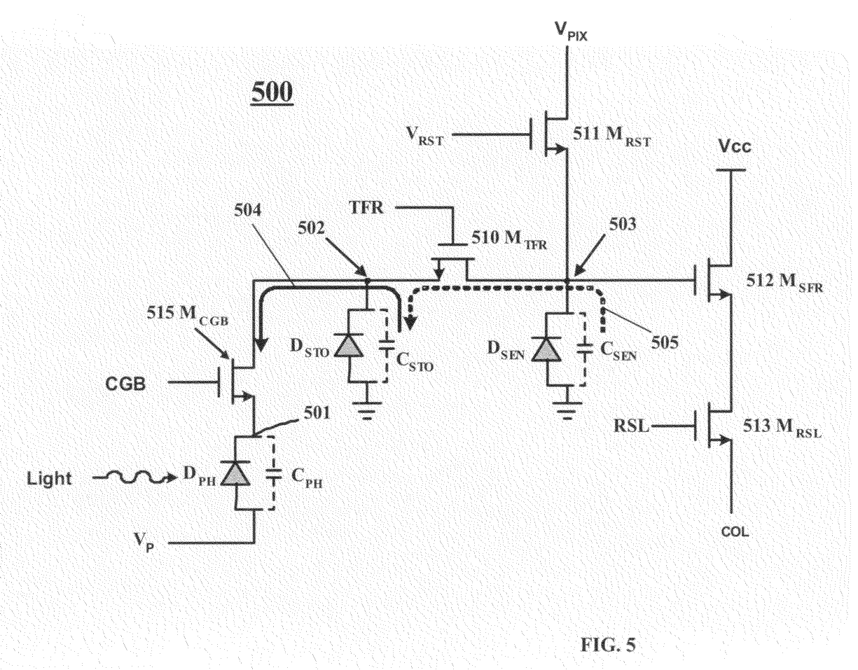

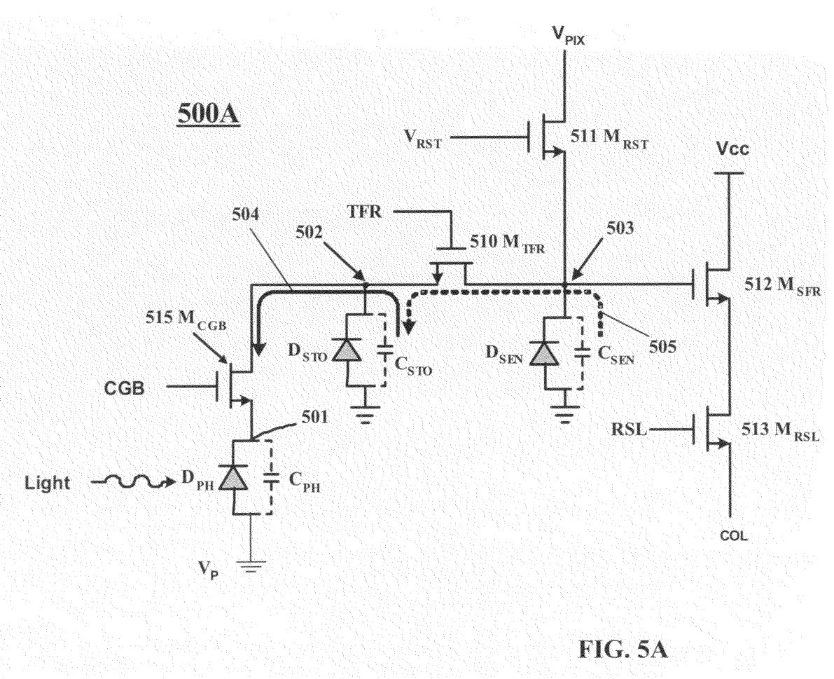

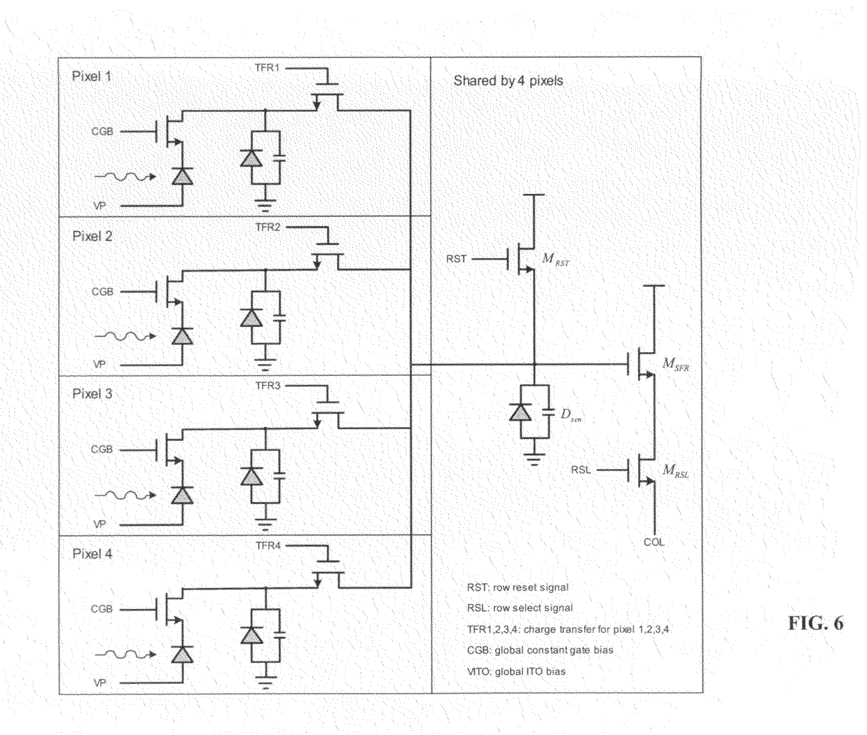

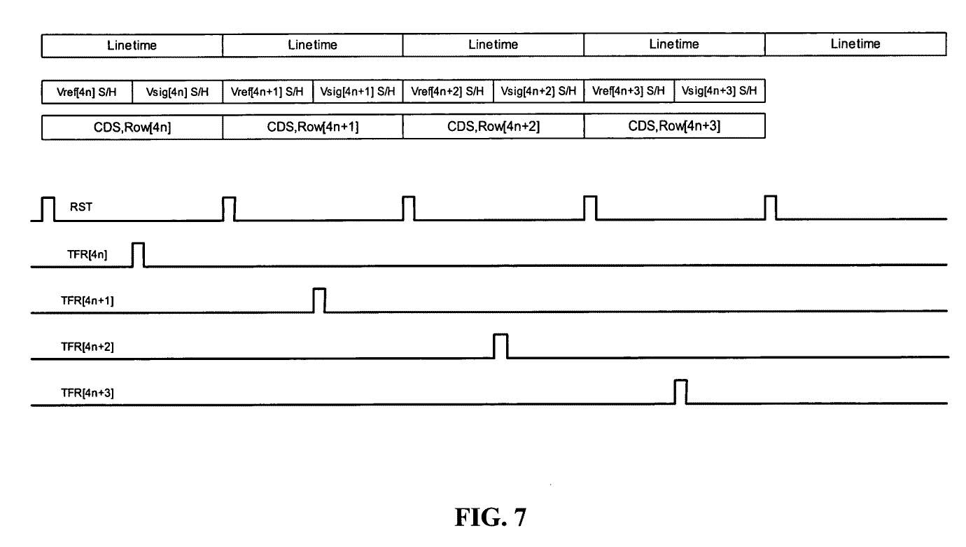

The third and fourth preferred embodiment of the pixel circuits are shown in FIGS. 5 and 5A. This embodiment combines features of the four transistor pixel circuits described in the previous section and the prior art pinning technology and correlated double sampling, all discussed in the background section to provide a sensor with substantially zero clock noise. The result is a sensor with greatly improved sensitivity and dark leakage tolerance over typical prior art CMOS and hybrid sensors.

### The Fifth Transistor

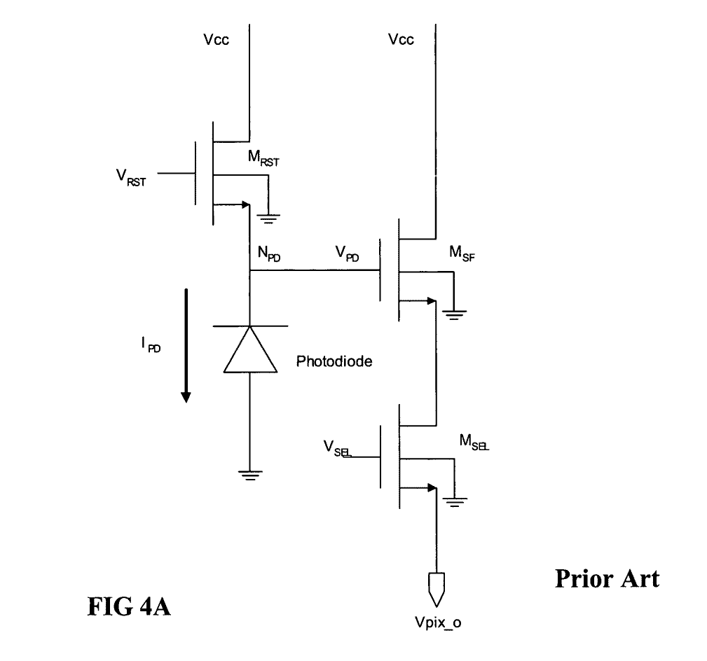

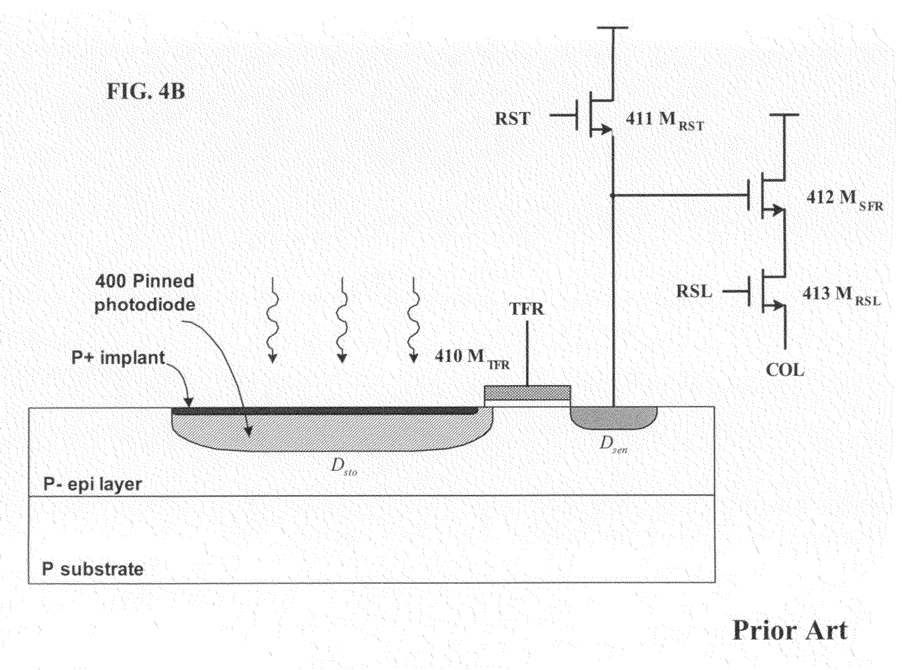

This preferred embodiment utilizes the four pixel transistor pixel design shown in FIG. 4. In addition, as in the First and Second Pixel Circuit design, Applicant adds a fifth transistor 515. This is a constant-gate-bias transistor that functions to separate a charge collecting node 501 from a charge-integration node 502 as shown in FIG. 5 and maintain the voltage drop between the charge collection node 501 and V_{P} constant. The photodiode structure is only responsible for generating electron-hole pairs (electrical charges). The charge collecting node 501 also includes a conductive n-type doping region if a p-type substrate is used. Transistor 515 is an NMOS transistor and is biased at a constant voltage to maintain the node 501 at an approximately constant voltage potential throughout the charge integration process during each integration period. In practice this voltage is made programmable to fine tune the performance of the pixel empirically. This voltage is preferably programmable in the range of 0.7V to 2.1V. As explained above, with this constant gate bias transistor, the transistor 515 would be operated under a condition under which, during integration cycles, any additional charges entering node 501 (i.e. electrons migrating from the photodiode regions) would be swept through the channel of constant gate bias transistor 515 into the charge integration node 502 to maintain a constant voltage at node 501. A special preferred embodiment of the present invention is shown in FIG. 5A which is exactly the same as FIG. 5 except V_{P} is at ground potential.

Charge Integration Node with Pinned Diode

At the beginning of each cycle nodes 502 and 503 are preferably reset to a potential of about 2.6 volts, slightly lower than the gate ON voltage of V_{RST} (the gate “ON” voltage which is at 3.3 volts) and V_{PIX} is at 3.3V in this example. Node 501 is at a potential determined by constant gate bias transistor 515 where the gate is maintained at about 1.2 volt providing a potential at node 501 of about a few tenths of a volt below the gate voltage. Excessive charges collected at charge collecting node 501 are integrated at charge integration node 502. Preferably charge integration node 502 is specially engineered so that, when the transfer-gate 510 is turned on, all of the charge collected at charge integration node 502 is completely transferred to charge sensing node 503. This is accomplished with a pinned diode D_{STO} that is made similar to the prior art pinned photodiode shown at 400 in FIG. 4B. This principle has been practiced in the charge-coupled-device technology to improve charge transfer efficiency and these designs are referred to as “buried channel” designs. In this invention, the pinned diode is used as a charge storage diode not as a photodiode.

### Charge Sensing Node

The charge sensing node 503 is connected to the gate of the source follower transistor 512. The charges collected in the photodiode regions of each of the pixels during integration (as well as some additional thermally generated charges) when transferred to node 503 results in partial discharge of the effective capacitance of diode D_{SEN}. This discharge results in an electrical potential drop at node 503 from the reset potential, which is proportional to the photon-generated charges collected in the photodiode plus the thermally generated charges. This electric potential is placed on the gate of source follower transistor 512 of each of the pixels. This charge is then amplified by the source follower circuitry as is the standard technique for these types of sensors as explained in the several patents referenced in the background section.

Variants of Photodiodes in Conjunction with Various Pixel Circuits

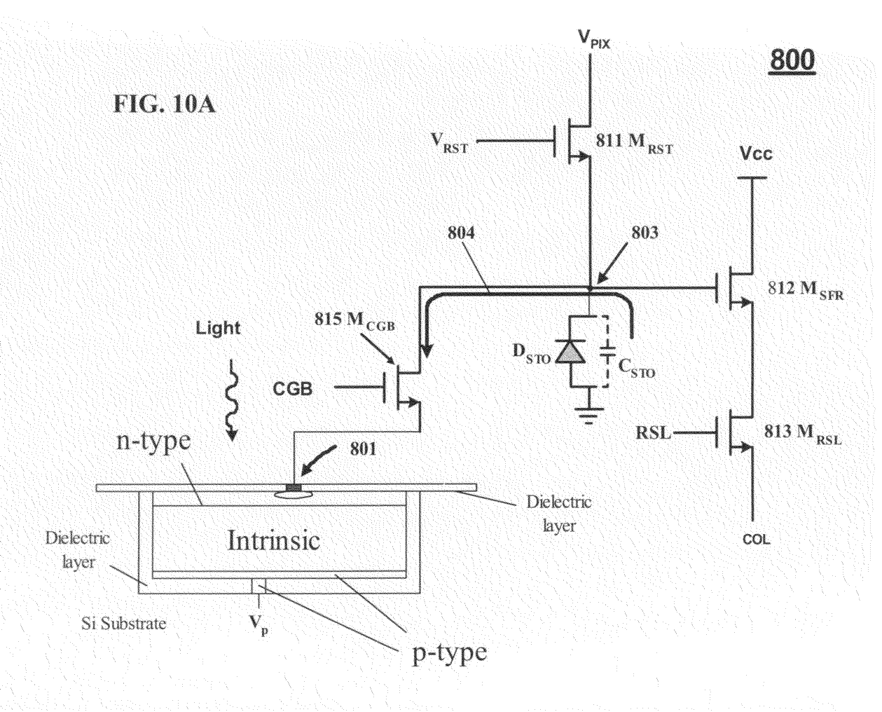

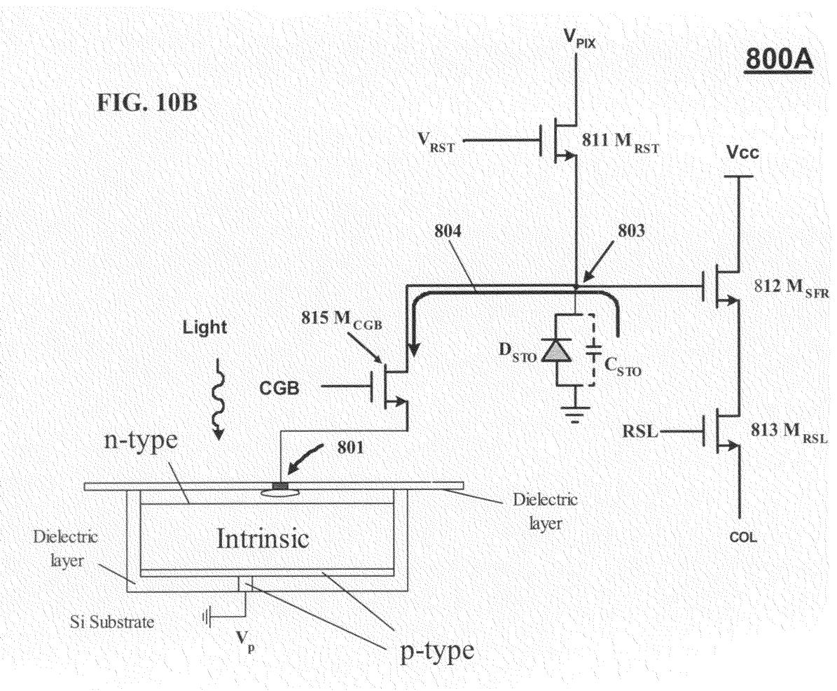

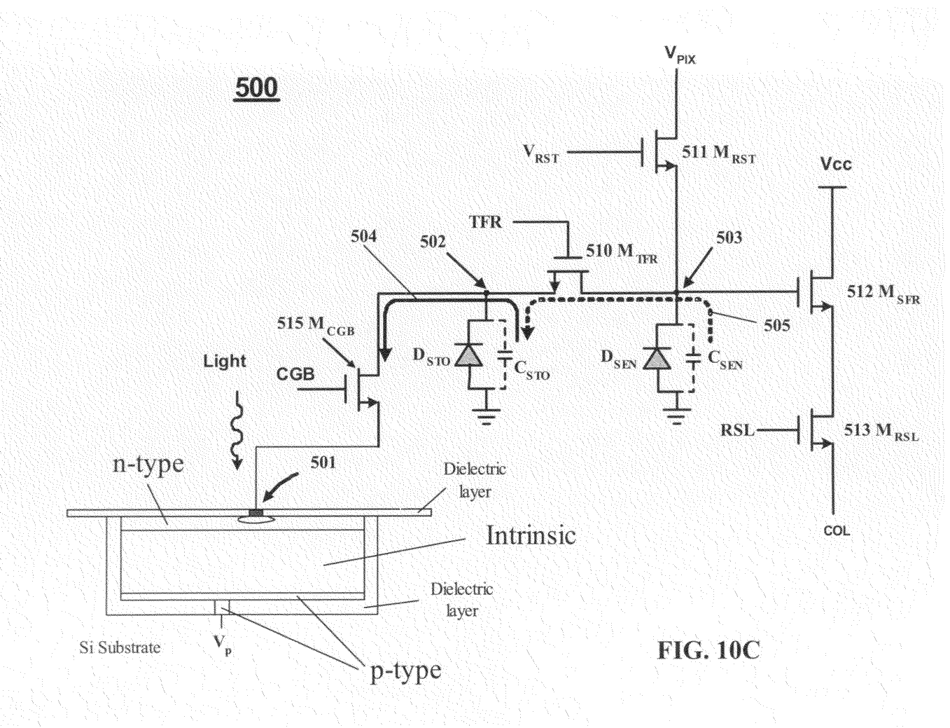

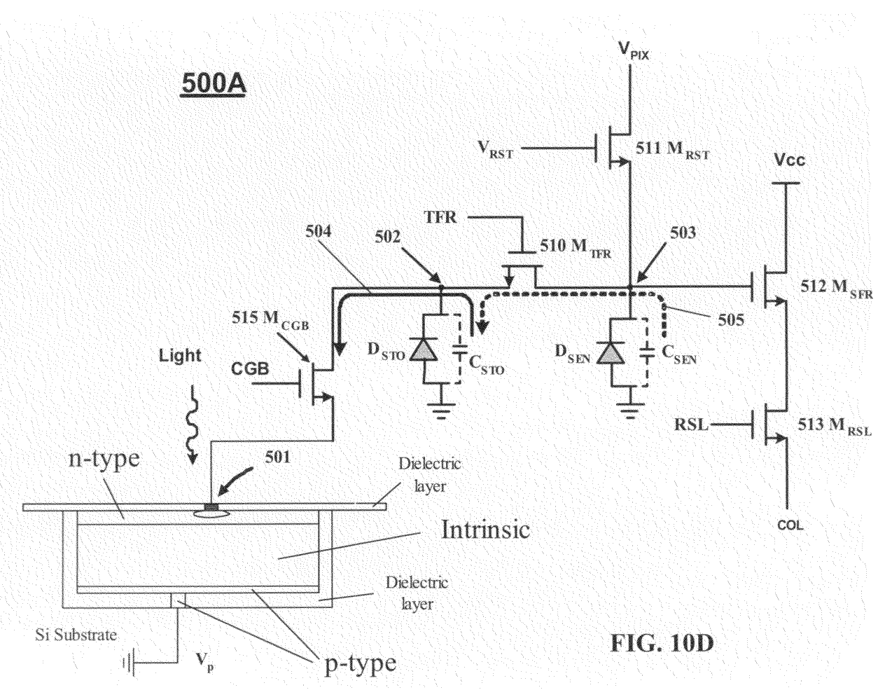

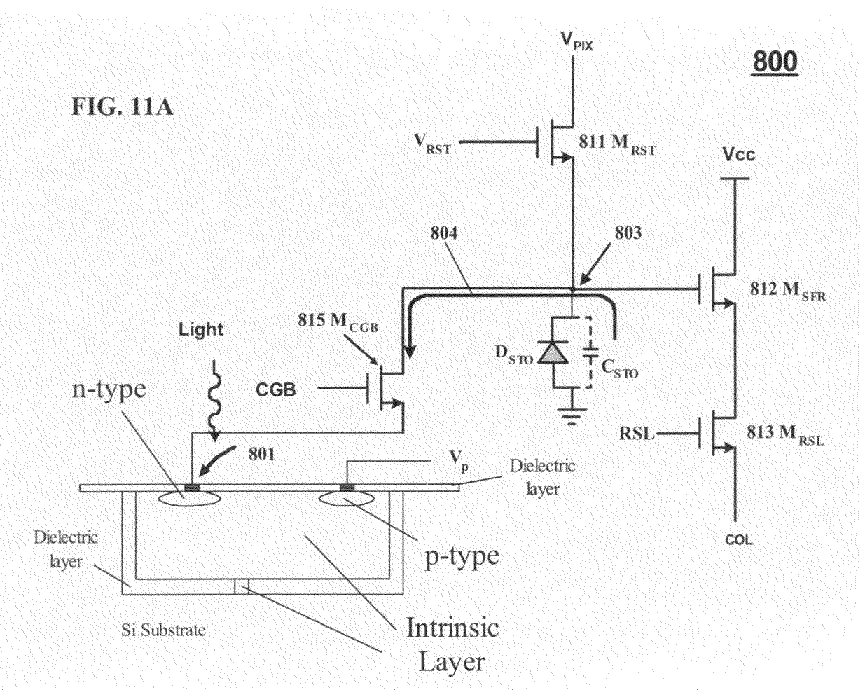

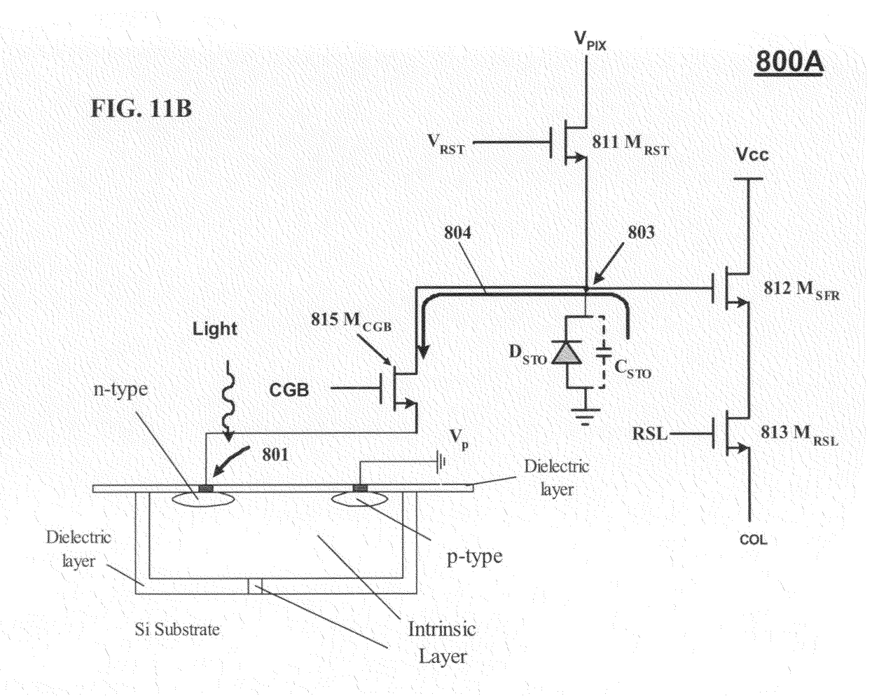

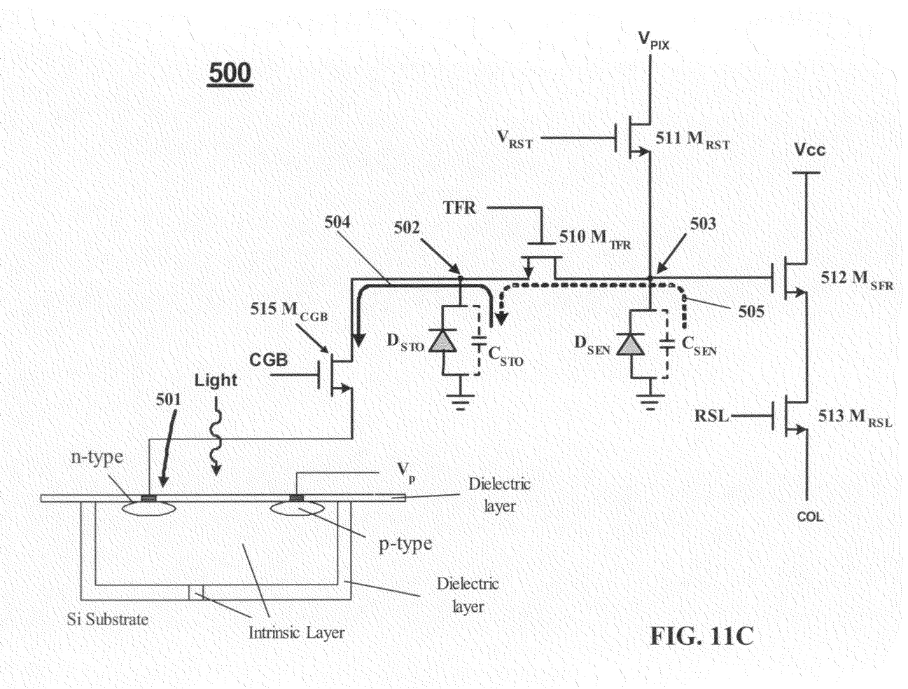

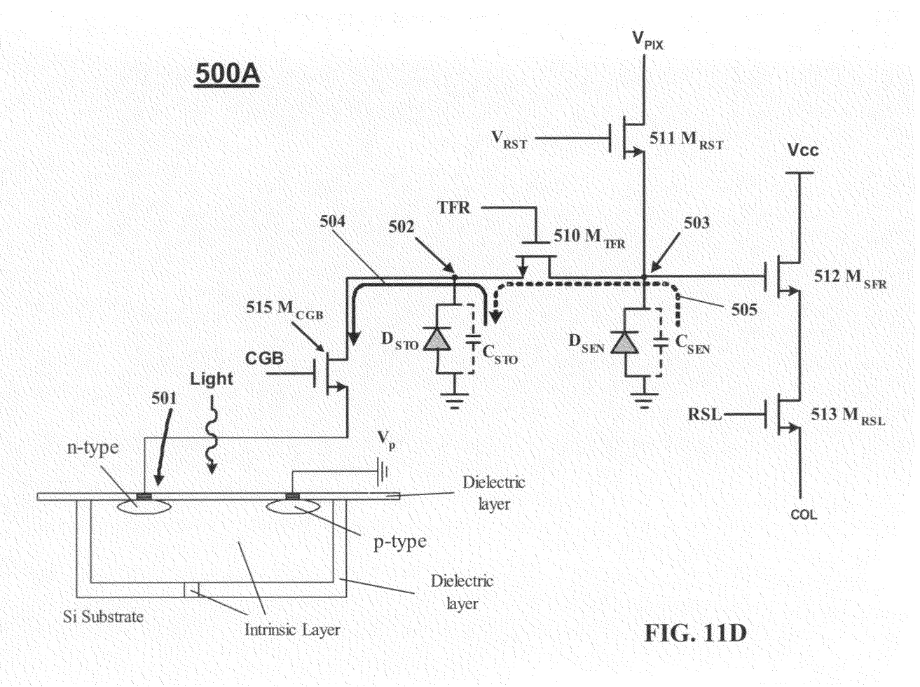

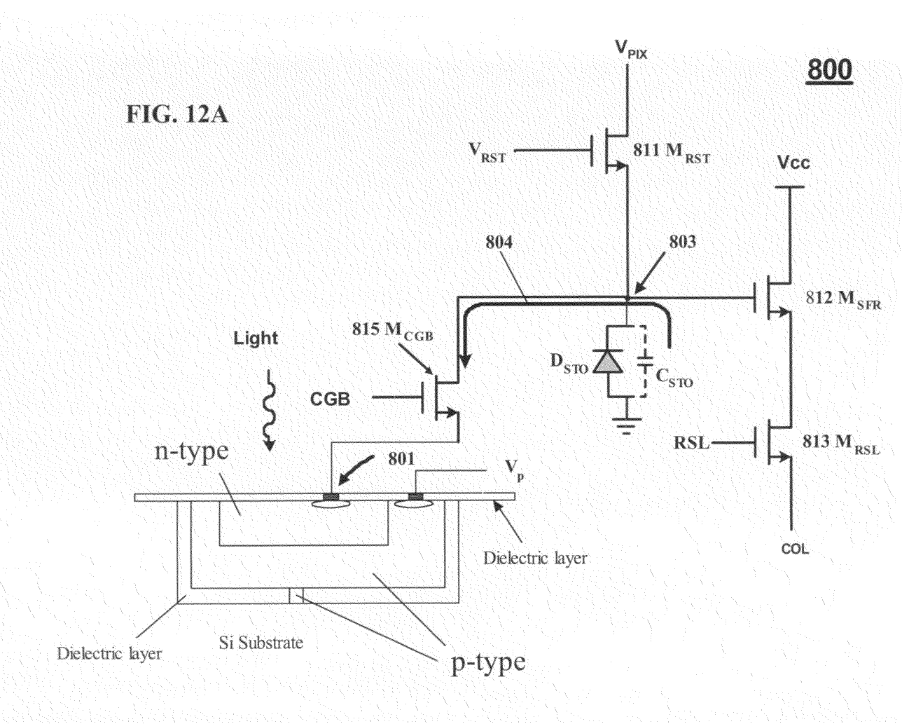

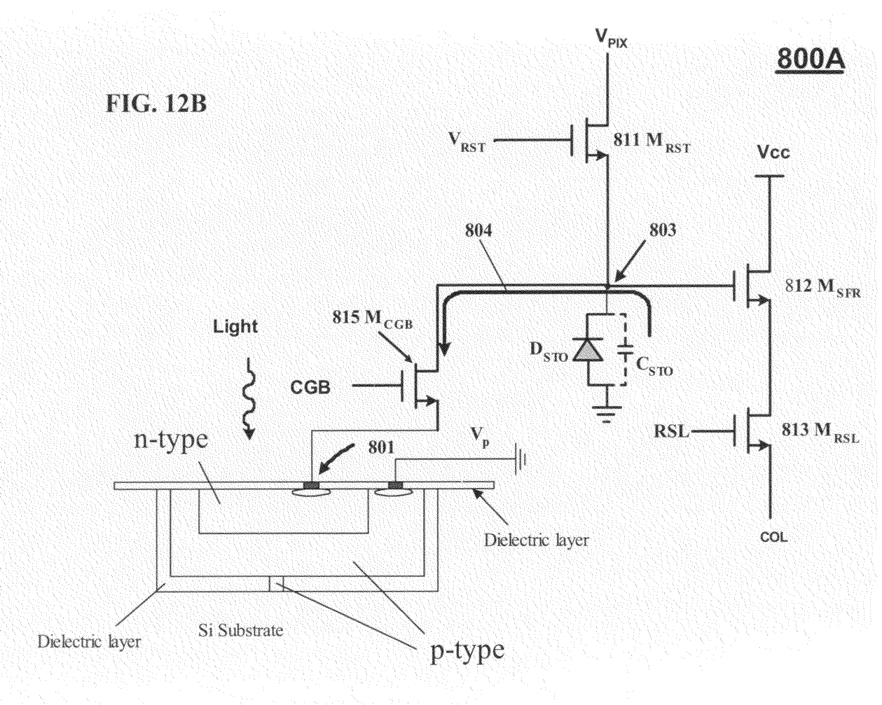

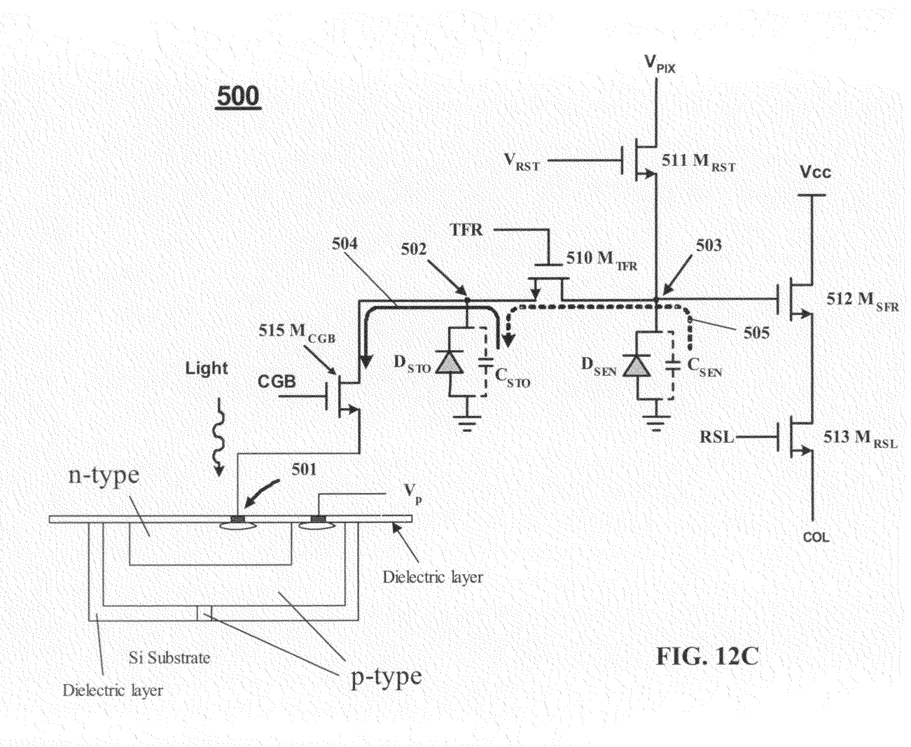

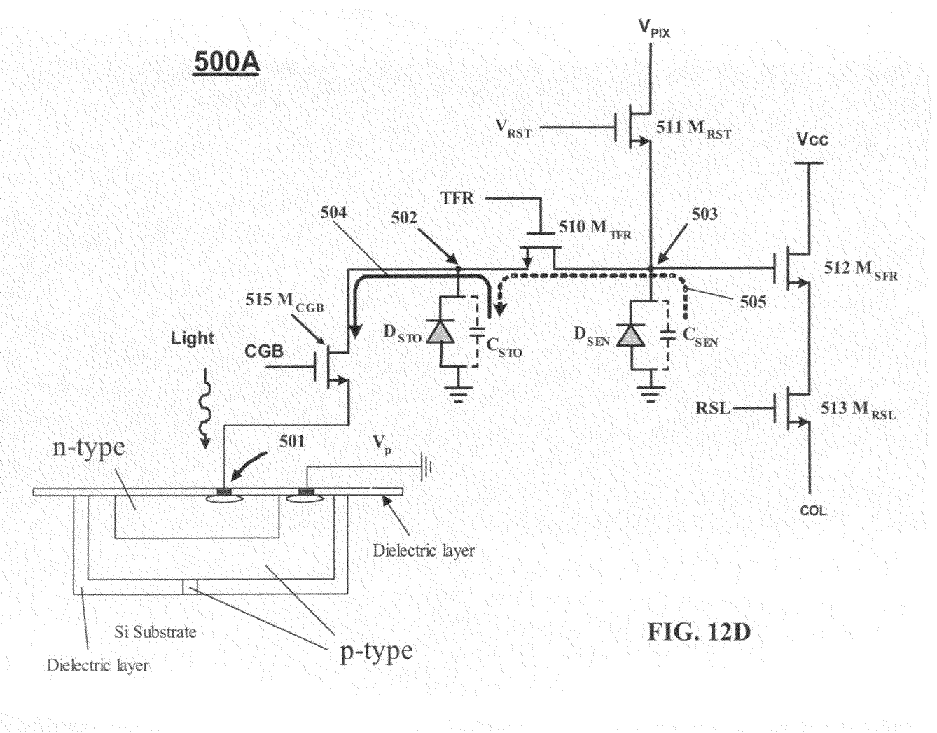

We can use the pixel circuits described in the preceding sections with the photodiode island array shown in FIGS. 1F, 2F and 3F to make various embodiments. For example, as shown in FIGS. 10A and 10B, the four transistor pixel circuits as shown in FIGS. 8 and 8A are used in conjunction with the photodiode island array of FIG. 1F. And, FIGS. 10C and 10D apply the five transistor pixel circuits as shown in FIGS. 5 and 5A. Different variants are shown in FIGS. 11A to 11D and 12A to 12D.

### Other Photodiode Materials

Several embodiments of the present invention are described in detail proposing the use of crystalline germanium epitaxially formed in islands in a silicon substrate to produce photodiode arrays useful for providing image sensors sensitive in the low energy infrared spectral ranges. Persons skilled in the teaching of the present application will realize that the teachings of this application can be applied to other spectral ranges by use of different materials. For example semiconductor substrates other than silicon such as germanium and combinations of Group III and V could be used. Other photodiode materials could be deposited to create the photodiode islands. For example, silicon is preferred to the spectral range of 190-1100 nm; indium gallium arsenide is preferred for the spectral range of 700 to 2600 nm, indium antimonide is preferred for the range of 1000-5500 nm, indium arsenide for the range of 1000-3800 nm, and platinum silicide is preferred for the range 1000 to 5000 nm. Germanium is preferred for the spectral range of 400 to 1700 nm. In the island, lattice matching buffer layer made of different materials may be used to reduce the lattice mismatch between the substrate and the photo-sensing layers. For example, one can use SiₓGe₁₋ₓ as the buffer by gradually decreasing the Si concentration to grow all Ge epitaxial layer on silicon substrate. In other examples, germanium can be used as the lattice mismatch buffer to grow III-V materials on silicon substrate. Indium phosphide may be used in conjunction with germanium to grow indium gallium arsenide on silicon substrate. Other known methods for providing epitaxial crystalline growth of the photodiode material in the photodiode islands are possible variations. The polarity shown in the examples can be changed. For example the substrate can be n-type instead of p-type or to make a large and deep n-type doping region (N-well) inside the p-type substrate and form islands inside such N-well. Another example in the layer examples the bottom layer could be doped n-type and the top layer doped p-type. In this invention, the author describes methods to grow photo-sensing island regions before making pixel and other circuits. This sequence can be reversed and have pixel and other circuits fabricated first, and then make the photo-sensing island regions. The substrate described in the method also includes silicon-on-insulator (SOI) substrate where a layered silicon-insulator-silicon substrate is used in place of the conventional silicon substrates.

The width of the holes penetrating through the dielectric materials can vary from a size less than the thickness of the dielectric material at the bottom to a size as large as the width of the island. The purpose of this hole as explained above is to enable the epitaxial growth of the electromagnetic radiation detection material relying on the crystalline structure of the substrate. In general the larger the width of the holes, the poorer the quality of the epitaxial films grown in such cavity will be; however, good or excellent epitaxial growth may not be required. If it is, a post high temperature anneal may improve the quality to be useful. Additionally, multiple holes can be used in each island as well.

While there have been shown what are presently considered to be preferred embodiments of the present invention, it will be apparent to those skilled in the art that various changes and modifications can be made herein without departing from the scope and spirit of the invention. In this application and in the claims the term photodiode is meant to include any photo-detector adapted to detect photons using n and p type materials including photo-capacitors, n-p photodiodes, n-i-p photodiodes, n-p-n as well as p-n-p photo-detectors, and hetero-junction photodiode made of multiple layers of III-V materials such as the hetero-junction photodiode made of Galium Nitride (GaN) and Aluminum Galium Nitride (AlGaN) or Galium Arsenide (GaAs) and Aluminum Galium Arsenide (AlGaAs). The sensor could be adapted for imaging infrared, ultraviolet light or x-rays by use of appropriate infrared, ultraviolet or x-ray absorbing material in the photodiode layer. Also, the sensor could be adapted for imaging x-ray by applying a surface layer (such as cesium iodide) adapted to absorb x-rays and to produce lower energy radiation that in turn is converted into electrical charges in the photodiode layer. Many CMOS circuit designs currently in use could be adapted using the teachings of the present invention to produce many million pixel arrays. The signal charges can be holes instead of electrons; the charge integration diode can be pinned or not pinned (especially if a perfect Si—SiO interface can be made someday); the charge sensing diode can be pinned; a metal-insulator-metal capacitor may be provided in parallel to the p-n junction diode to provide additional effective capacitance of the charge sensing node; there can be a metal-insulator-metal capacitor made in parallel to the pinned diode for charge integration to increase the charge storage capacity at that node. We can use combination of p-MOS and n-MOS transistors to implement the reset transistor and row select transistor. We can use an operational amplifier (Op-Amp) in the pixel circuit to hold the photodiode at a constant potential. We can use multiple transistors to implement the source-follower circuit; we can add additional transistors other than the transistors described above to add new functionality on a pixel level, such as analog-to-digital conversion, peak detection, voltage thresholding and demodulation. In the preferred embodiment, shown in FIGS. 5 and 5A, the Applicant describes a mode with which the drain of the reset transistor (denoted as V_{PIX}) is an NMOS transistor and is set at the supply voltage (3.3V). When the reset transistor M_{RST} is turned ON (under which its gate is set at the supply voltage (3.3V), the sense node will be reset to 2.6V (700 mV, the threshold voltage of a transistor, below the gate voltage). This is known in the industry as “soft reset”; and it is known in the industry that “soft reset” provides better noise immunity but poor linearity when the signal is small. To combat the linearity problem, one alternative operation mode is to set V_{PIX} at least 700 mV (the threshold voltage) below the “ON” voltage of the gate (3.3V). Typically, one would set V_{PIX} at 2.2-2.4V to avoid the variation of threshold voltage due to process. This is called “Hard Reset”. Under hard reset mode, the sense node will be reset to V_{PIX}. It is also known in the industry that Hard Reset is good for linearity but has poor performance in “noise immunity”. One can also combine the hard and soft reset within a sense node reset cycle to achieve a compromised performance in “linearity” and “noise immunity”. All of these modes, hard reset, soft reset, hard and soft combination, can be used with this present invention to achieve the desirable performance required in different applications. Of course, the applicant uses 3.3V and 700 mV to describe the supply voltage and the threshold voltage of the transistor only as example. The people skilled in the field are aware that the threshold voltage can vary from one CMOS process to another and the supply voltage can be different from 3.3V. One can even use transistor of different threshold voltage separately for the constant gate bias, reset, row-select, transfer and source follower transistors in the pixel circuit. Once can also use a PMOS transistor for the reset transistor M_{RST}. These variants are also obvious derivatives of the preferred embodiment.

Therefore, the scope of the invention should be determined by the appended claims and their legal equivalents and not by the examples that have been given.

What is claimed is:

1. A MOS or CMOS based active pixel sensor comprising:
A) a substrate comprised of a substrate material;
B) an array of pixels fabricated in or on said substrate, each pixel comprising:
1) pixel circuits, and
2) an electromagnetic radiation detection structure, in the form of an island isolated from the electromagnetic radiation detection structures of other pixels in said array, for converting electromagnetic radiation into charges, said electromagnetic detection structure defining a photo-sensing element for each of said pixels, comprising:
a. at least two regions of charge generating material to generate charges upon the absorption of electromagnetic radiation,
b. at least one electrode element in electric communication with the pixel integrating circuits,
wherein each of said pixel circuits:
A) defines:
1) a charge collection node on which charges generated inside said electromagnetic radiation detection region are collected,
2) a charge integration node, at which charges generated in said pixel are integrated to produce pixel signals, and
3) a charge sensing node from which reset signals or the pixel signals are sensed, which charge sensing node may be the same node as the charge integration node or the charge sensing node may be different from the charge integration node; and
B) is adapted to maintain voltage potential drop across said electromagnetic radiation detection structure substantially constant during charge integration cycles.

2. The sensor as in claim 1 wherein said electromagnetic radiation detection structures are comprised substantially of electromagnetic radiation detection material different from said substrate material.

3. The sensor as in claim 2 wherein said substrate material is crystalline silicon and said electromagnetic radiation detection material is substantially all hydrogenated amorphous silicon.

4. The sensor as in claim 2 wherein said substrate material is crystalline silicon and said electromagnetic radiation detection material is substantially all germanium.

5. The sensor as in claim 4 wherein said germanium is microcrystalline germanium.

6. The sensor as in claim 4 wherein said germanium is polycrystalline germanium.

7. The sensor as in claim 4 wherein said germanium is single crystalline germanium.

8. The sensor as in claim 2 wherein said substrate material is crystalline silicon and said electromagnetic radiation detection material is chosen from a group consisting of silicon, germanium, indium gallium arsenide, indium arsenide, platinum silicide and indium antimonide.

9. The sensor as in claim 2 wherein said electromagnetic radiation detection structure is separated almost entirely from said substrate by a dielectric material.

10. The sensor as in claim 9, wherein said dielectric material comprises of silicon oxide.

11. The sensor as in claim 9 wherein said electromagnetic radiation structure is in contact with said substrate through at least a hole in said dielectric material.

12. The sensor as in claim 11, wherein said dielectric material defines a thickness in a region along a bottom portion of said island and said hole has a width smaller than the thickness of the dielectric material.

13. The sensor as in claim 11 wherein said hole has a width of less than one micron and the radiation detection material is a material grown epitaxially through said hole utilizing the substrate material as a crystalline seed.

14. The sensor as in claim 11 wherein each said electromagnetic radiation detection structure includes at least a lattice matching buffer region adapted to grow said radiation detection material from said substrate.

15. The sensor as in claim 2 wherein a bottom portion of said electromagnetic radiation detection structure is substantially or entirely in contact with said substrate.

16. The sensor as in claim 1 wherein said electromagnetic radiation detection material is comprised of semiconductor materials.

17. The sensor as in claim 16 wherein said at least two regions of charge generating material includes an n-doped region and a p-doped region.

18. The sensor as in claim 16 wherein said at least two regions of charge generating material has at least three regions of charge generating material and includes an n-doped region, an intrinsic region and a p-doped region.

19. The sensor as in claim 1 wherein said pixel circuits are positioned at least partially below said electromagnetic radiation detection structures.

20. The sensor as in claim 1 wherein said pixel circuits are positioned along sides of said electromagnetic radiation detection structures.

21. The sensor as in claim 1 wherein said pixel circuits are adapted to maintain voltage potential across said electromagnetic radiation detection structures at less than 1.0 volts and substantially constant during charge integration cycles.

22. The sensor as in claim 1 wherein said pixel circuits are adapted to maintain voltage potential across said electromagnetic radiation detection structures at less than 0.5 volts and substantially constant during charge integration cycles.

23. The sensor as in claim 1 wherein said pixel circuits are adapted to maintain voltage potential across said electromagnetic radiation detection structures approximately zero volts and substantially constant during charge integration cycles.

24. The sensor as in claim 1 wherein said charge integration node and said charge sensing node for each said pixel are the same node.

25. The sensor as in claim 1 wherein within each pixel said charge integration node is separated from said charge sensing node by circuit elements.

26. The sensor as in claim 1 wherein within each said pixel said charge collection node is separated from said charge integration node by circuit elements.

27. The sensor as in claim 26 wherein said circuit elements comprise of a transistor.

28. The sensor as in claim 27 wherein within each said pixel said transistor comprises a gate that is held at a substantially constant potential during charge integration cycles.

29. The sensor as in claim 26 wherein said circuit elements include an operational amplifier.

30. The sensor as in claim 1 wherein in each pixel said electromagnetic radiation detection structure is in electrical communication with said pixel circuits through said at least one electrode element.

31. The sensor as in claim 1 wherein each electromagnetic radiation detection structure comprises two electrodes comprised of conducting regions in electrical communication with said pixel circuits.

32. The sensor as in claim 1 wherein the pixel circuits for each pixel comprises at least four transistors.

33. The sensor as in claim 1 wherein each of said pixel circuits comprises four transistors.

34. The sensor as in claim 1 wherein each of said pixel circuits comprise five transistors.

35. The sensor as in claim 1 wherein each of said integrated pixel circuits comprise six transistors.

36. The sensor as in claim 1 wherein said sensor is adapted for correlated double sampling.

37. The sensor as in claim 1 wherein said pixel circuits of each pixel comprises a constant bias transistor adapted to maintain the potential across said electromagnetic radiation detection structure substantially constant.

38. The sensor as in claim 1 wherein said pixel circuits of each pixel comprises a pinned diode adapted to store charges providing an electrical potential at said charge integration node.

39. A MOS or CMOS based active pixel sensor comprising:
A) a substrate comprised of a substrate material;
B) an array of pixels fabricated in or on said substrate, each pixel comprising:
1) pixel circuits, and
2) an electromagnetic radiation detection structure in the form of an island isolated from the electromagnetic radiation detection structures of other pixels in said array for converting electromagnetic radiation into charges, said electromagnetic detection structure defining a photo-sensing element for each of said pixels, comprising:
a. at least two regions of charge generating material to generate charges upon the absorption of electromagnetic radiation, and
b. at least one electrode element in electric communication with the pixel integrating circuits.
wherein each of said pixel circuits:
A) defines:
1) a charge collection node on which charges generated inside said electromagnetic radiation detection region are collected, and
2) a common charge integration and sensing node, at which charges generated in said pixel are integrated to produce pixel signals and from which reset signals or the pixel signals are sensed.
B) is adapted to maintain voltage potential drop across said electromagnetic radiation detection structure substantially constant during charge integration cycles, and
C) comprises:
1) circuit elements separating said charge collection node from said common charge integration and sensing node,
2) circuit elements having electrical capacitance adapted to store charges providing an electrical potential at said common charge integration and sensing node,
3) circuit elements adapted to reset said common charge integration and sensing node,
4) circuit elements adapted to convert charges on said common charge integration and sensing node into electrical signals, and
5) circuit elements adapted to readout the electrical signals.

40. A MOS or CMOS based active pixel sensor comprising:
A) a substrate comprised of a substrate material;
B) an array of pixels fabricated in or on said substrate, each pixel comprising:
1) pixel circuits, and
2) an electromagnetic radiation detection structure in the form of an island isolated from the electromagnetic radiation detection structures of other pixels in said array for converting electromagnetic radiation into charges, said electromagnetic detection structure defining a photo-sensing element for each of said pixels, comprising:
a. at least two regions of charge generating material to generate charges upon the absorption of electromagnetic radiation,
b. at least one electrode element in electric communication with the pixel integrating circuits,
wherein each of said pixel circuits:
A) defines:
1) a charge collection node on which charges generated inside said electromagnetic radiation detection region are collected,
2) a charge integration node, at which charges generated in said pixel are integrated to produce pixel signals, and
3) a charge sensing node from which reset signals and the pixel signals are sensed;
B) is adapted to maintain voltage potential drop across said electromagnetic radiation detection structure substantially constant during charge integration cycles, and
C) comprises:
1) circuit elements separating said charge collection node from said charge integration node,
2) circuit elements having electrical capacitance adapted to store charges providing an electrical potential at said charge integration node,
3) circuit elements adapted to control charges flowing between said charge integration node and said charge sensing node,
4) circuit elements adapted to reset said charge integration node,
5) circuit elements adapted to reset said charge sensing node,
6) circuit elements adapted to convert charges on said charge sensing node into electrical signals, and
7) circuit elements adapted to readout the electrical signals.
